(19) United States
(12) Patent Application Publication
(10) Pub. No.: US 2025/0169060 A1
(43) Pub. Date: May 22, 2025

(54) MEMORY DEVICE

(71) Applicant: SEMICONDUCTOR ENERGY LABORATORY CO., LTD., Atsugi-shi, Kanagawa-ken (JP)

(72) Inventors: Shunpei YAMAZAKI, Setagaya, Tokyo (JP); Tatsuya ONUKI, Atsugi, Kanagawa (JP); Hitoshi KUNITAKE, Machida, Tokyo (JP)

(21) Appl. No.: 18/837,718

(22) PCT Filed: Feb. 3, 2023
(86) PCT No.: PCT/IB2023/050939

§ 371 Date: Aug. 12, 2024

(30) Foreign Application Priority Data
Feb. 18, 2022 (JP) 2022-023699

(51) Int. Cl. H10B 12/00; H01L 25/07; H10B 80/00

(52) U.S. Cl. CPC H10B 12/315; H01L 25/074; H10B 80/00; H01L 2225/06541

(57) ABSTRACT

A memory device that can be scaled down or highly integrated is provided. The memory device includes a first transistor, a second transistor, a third transistor, a first capacitor, and a second capacitor. The first capacitor includes a first electrode and a second electrode. The second capacitor includes the first electrode and a third electrode. One of a source and a drain of the first transistor is electrically connected to the second electrode. One of a source and a drain of the second transistor is electrically connected to the third electrode. A gate of the third transistor is electrically connected to the second electrode. The first electrode includes a portion overlapping with each of the second electrode, the third electrode, the first transistor, and the second transistor, and is supplied with a fixed potential or a ground potential.

### TECHNICAL FIELD

One embodiment of the present invention relates to a semiconductor device, a memory device, and an electronic device. Another embodiment of the present invention relates to a method for manufacturing a semiconductor device.

Note that one embodiment of the present invention is not limited to the above technical field. Examples of the technical field of one embodiment of the present invention include a semiconductor device, a display device, a light-emitting device, a power storage device, a memory device, an electronic device, a lighting device, an input device (e.g., a touch sensor), an input/output device (e.g., a touch panel), a method for driving any of them, and a method of manufacturing any of them.

In this specification and the like, a semiconductor device generally means a device that can function by utilizing semiconductor characteristics. A semiconductor element such as a transistor, a semiconductor circuit, an arithmetic device, and a memory device are each one embodiment of a semiconductor device. It can be sometimes said that a display device (a liquid crystal display device, a light-emitting display device, and the like), a projection device, a lighting device, an electro-optical device, a power storage device, a memory device, a semiconductor circuit, an imaging device, an electronic device, and the like include a semiconductor device.

### BACKGROUND ART

In recent years, semiconductor devices such as LSI (Large Scale Integration), CPUs (Central Processing Units), and memories (memory devices) have been developed. These semiconductor devices have been used in various electronic devices such as computers and portable information terminals. In addition, memories under development employ various storage systems for intended uses such as temporary storage at the time of executing arithmetic processing and long-term storage of data. Examples of memories with typical storage systems include a DRAM (Dynamic Random Access Memory), an SRAM (Static Random Access Memory), and a flash memory.

With an increase in the amount of data dealt with, semiconductor devices having larger memory capacity have been required. Patent Document 1 and Non-Patent Document 1 each disclose a memory cell including stacked transistors.

### REFERENCES

### Patent Document

[Patent Document 1] PCT International Publication No. 2021/053473

### Non-Patent Document

[Non-Patent Document 1] M. Oota, et al., “3D-Stacked CAAC-In—Ga—Zn Oxide FETs with Gate Length of 72 nm”, IEDM Tech. Dig., 2019, pp. 50-53

### SUMMARY OF THE INVENTION

### Problems to be Solved by the Invention

An object of one embodiment of the present invention is to provide a semiconductor device or a memory device that can be scaled down or highly integrated. Another object of one embodiment of the present invention is to provide a semiconductor device or a memory device with a high operating speed. Another object of one embodiment of the present invention is to provide a semiconductor device or a memory device having excellent electrical characteristics. Another object of one embodiment of the present invention is to provide a semiconductor device or a memory device with a small variation in electrical characteristics of transistors. Another object of one embodiment of the present invention is to provide a highly reliable semiconductor device or memory device. Another object of one embodiment of the present invention is to provide a semiconductor device or a memory device with a high on-state current. Another object of one embodiment of the present invention is to provide a semiconductor device or a memory device with low power consumption. Another object of one embodiment of the present invention is to provide a novel semiconductor device or memory device.

Another object of one embodiment of the present invention is to provide a memory device having large memory capacity. Another object of one embodiment of the present invention is to provide a memory device occupying a small area. Another object of one embodiment of the present invention is to provide a highly reliable memory device. Another object of one embodiment of the present invention is to provide a memory device with low power consumption. Another object of one embodiment of the present invention is to provide a novel memory device.

Note that the description of these objects does not preclude the presence of other objects. One embodiment of the present invention does not need to achieve all of these objects. Other objects can be derived from the description of the specification, the drawings, and the claims.

### Means for Solving the Problems

One embodiment of the present invention is a memory device including a first transistor, a second transistor, a third transistor, a first capacitor, and a second capacitor. The first capacitor includes a first electrode and a second electrode. The second capacitor includes the first electrode and a third electrode. One of a source and a drain of the first transistor is electrically connected to the second electrode. One of a source and a drain of the second transistor is electrically connected to the third electrode. A gate of the third transistor is electrically connected to the second electrode. The first electrode includes a portion overlapping with each of the second electrode, the third electrode, the first transistor, and the second transistor, and is supplied with a fixed potential or a ground potential.

In the above, the first electrode preferably includes a portion positioned above the first transistor and a portion positioned on a side of the first transistor.

In the above, a connection electrode is preferably further included. In that case, the other of the source and the drain of the first transistor is preferably electrically connected to the connection electrode and the other of the source and the drain of the second transistor is preferably electrically connected to the connection electrode.

In the above, the other of the source and the drain of the first transistor preferably includes a first conductive layer. The other of the source and the drain of the second transistor preferably includes a second conductive layer. In that case, the connection electrode preferably includes a portion in contact with a top surface of the first conductive layer, a portion in contact with a side surface of the first conductive layer, a portion in contact with a top surface of the second conductive layer, and a portion in contact with a side surface of the second conductive layer.

In the above, a fourth transistor and a third capacitor are preferably further included. In that case, the fourth transistor and the third capacitor are preferably positioned below the first transistor. The third capacitor preferably includes a fourth electrode and a fifth electrode, and the fourth electrode is preferably supplied with a ground potential or a fixed potential. One of a source and a drain of the fourth transistor is electrically connected to the fifth electrode, and the other of the source and the drain of the fourth transistor is electrically connected to the connection electrode.

In the above, the other of the source and the drain of the fourth transistor preferably includes a third conductive layer. In that case, the connection electrode preferably includes a portion in contact with a top surface of the third conductive layer and a portion in contact with a side surface of the third conductive layer.

In the above, the first electrode preferably includes a portion positioned on a side of the fourth transistor.

In the above, the fourth electrode is preferably electrically connected to the first electrode.

In the above, the first transistor preferably includes a semiconductor layer and a gate electrode. In that case, the fourth electrode preferably includes a portion positioned below the first transistor. The gate electrode preferably includes a portion overlapping with the fourth electrode with the semiconductor layer therebetween.

In the above, each of the first electrode and the second electrode preferably has a flat-plate shape. Alternatively, in the above, a top surface of the second electrode preferably has a depressed portion, and the first electrode preferably includes a protruding portion engaging with the top surface of the second electrode.

### Effect of the Invention

According to one embodiment of the present invention, a semiconductor device and a memory device that can be scaled down or highly integrated can be provided. According to one embodiment of the present invention, a semiconductor device and a memory device with a high operating speed can be provided. According to one embodiment of the present invention, a semiconductor device and a memory device with excellent electrical characteristics can be provided. According to one embodiment of the present invention, a semiconductor device and a memory device with a small variation in electrical characteristics of transistors can be provided. According to one embodiment of the present invention, highly reliable semiconductor device and memory device can be provided. According to one embodiment of the present invention, a semiconductor device and a memory device with a high on-state current can be provided. According to one embodiment of the present invention, a semiconductor device and a memory device with low power consumption can be provided. According to one embodiment of the present invention, novel semiconductor device and memory device can be provided.

According to one embodiment of the present invention, a memory device having large memory capacity can be provided. According to one embodiment of the present invention, a memory device occupying a small area can be provided. According to one embodiment of the present invention, a highly reliable memory device can be provided. According to one embodiment of the present invention, a memory device with low power consumption can be provided. According to one embodiment of the present invention, a novel memory device can be provided.

Note that the description of these effects does not preclude the presence of other effects. One embodiment of the present invention does not necessarily have all the effects. Other effects can be derived from the description of the specification, the drawings, and the claims.

### BRIEF DESCRIPTION OF THE DRAWINGS

FIG. 1A and FIG. 1B are diagrams illustrating a structure example of a memory device.

FIG. 2A and FIG. 2B are diagrams each illustrating a structure example of a memory device.

FIG. 3 is a diagram illustrating a structure example of a memory device.

FIG. 4 is a diagram illustrating a structure example of a memory device.

FIG. 5 is a diagram illustrating a structure example of a memory device.

FIG. 6 is a diagram illustrating a structure example of a memory device.

FIG. 7A to FIG. 7D are circuit diagrams each illustrating a structure example of a memory device.

FIG. 8 is a cross-sectional view illustrating a structure example of a semiconductor device.

FIG. 9A is a cross-sectional view illustrating a structure example of a semiconductor device. FIG. 9B is a cross-sectional view illustrating a structure example of a transistor.

FIG. 10 is a cross-sectional view illustrating a structure example of a semiconductor device.

FIG. 11 is a cross-sectional view illustrating a structure example of a semiconductor device.

FIG. 12 is a cross-sectional view illustrating a structure example of a semiconductor device.

FIG. 13 is a cross-sectional view illustrating a structure example of a semiconductor device.

FIG. 14 is a cross-sectional view illustrating a structure example of a semiconductor device.

FIG. 15A and FIG. 15B are plan views each illustrating a structure example of a semiconductor device

FIG. 16A and FIG. 16B are plan views each illustrating a structure example of a semiconductor device.

FIG. 17A and FIG. 17B are diagrams illustrating an example of a memory device.

FIG. 18A and FIG. 18B are circuit diagrams each illustrating an example of a memory layer.

FIG. 19 is a timing chart for describing an operation example of a memory cell.

FIG. 20A and FIG. 20B are circuit diagrams for describing an operation example of a memory cell.

FIG. 21A and FIG. 21B are circuit diagrams for describing an operation example of a memory cell.

FIG. 22 is a circuit diagram for describing a structure example of a semiconductor device.

FIG. 23A and FIG. 23B are diagrams illustrating an example of a semiconductor device.

FIG. 24A and FIG. 24B are diagrams illustrating examples of electronic components.

FIG. 25A to FIG. 25J are diagrams illustrating examples of electronic devices.

FIG. 26A to FIG. 26E are diagrams illustrating examples of electronic devices.

FIG. 27A to FIG. 27C are diagrams illustrating examples of electronic devices.

FIG. 28 is a diagram illustrating an example of a device for space.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

The position, size, range, and the like of each component illustrated in drawings do not represent the actual position, size, range, and the like in some cases for easy understanding. Therefore, the disclosed invention is not necessarily limited to the position, size, range, and the like disclosed in drawings.

Note that in this specification and the like, ordinal numbers such as “first” and “second” are used for convenience and do not limit the number of components or the order of components (e.g., the order of steps or the stacking order of layers). An ordinal number used for a component in a certain part in this specification is not the same as an ordinal number used for the component in another part in this specification or claims in some cases.

In this specification and the like, the term “film”, the term “layer”, and the term ending with “-or” can be interchanged with each other. For example, in some cases, the term “conductive layer” and the term “insulating layer” can be interchanged, respectively, with the term “conductive film” and the term “insulating film” or with the term “conductor” and the term “insulator”.

In this specification and the like, terms for describing positioning, such as “over”, “under”, “above”, and “below”, are sometimes used for convenience to describe the positional relationship between components with reference to drawings. The positional relationship between components is changed as appropriate in accordance with a direction in which each component is described. Thus, the positional relationship is not limited to the terms described in this specification and the like, and can be described with another term as appropriate depending on the situation. For example, the expression “an insulator positioned over a conductor” can be replaced with the expression “an insulator positioned under a conductor” when the direction of a drawing illustrating these components is rotated by 180°.

### Embodiment 1

In this embodiment, a memory device of one embodiment of the present invention will be described. One embodiment of the present invention relates to the memory device including a plurality of memory cells each including a transistor and a capacitor.

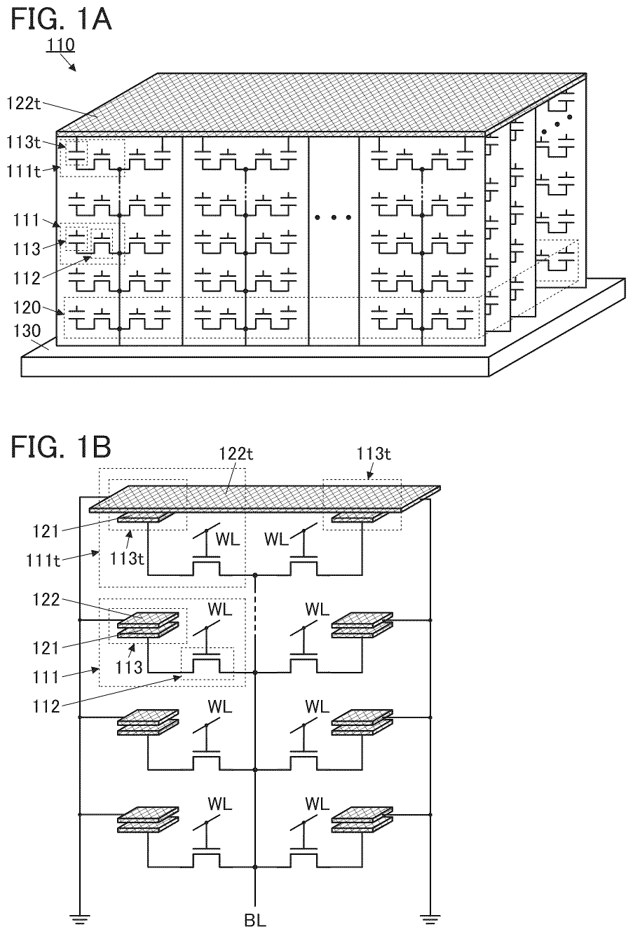

FIG. 1A is a schematic perspective view of a memory device 110 of one embodiment of the present invention.

The memory device 110 includes a plurality of memory cells 111 over a substrate 130. The memory cells 111 are arranged periodically three-dimensionally in the lateral direction, the depth direction, and the height direction. Each of the memory cells 111 includes at least a transistor 112 and a capacitor 113.

The substrate 130 may include a variety of circuits such as a control circuit, a logic circuit, and a memory circuit in addition to a driver circuit, a read circuit (including a sense amplifier), and a power supply circuit that are necessary for driving the memory cells 111, or an external connection terminal. As the substrate 130, a single crystal semiconductor substrate such as a silicon substrate or an SOI substrate is preferably used, for example.

In FIG. 1A, a plurality of memory cells 111 at the same level can be collectively referred to as a memory cell array 120. Although FIG. 1A illustrates an example of a case where five or more layers of the memory cell arrays 120 are stacked, the memory cell array 120 may be a single layer, or two or more layers and four or less layers of the memory cell arrays 120 may be stacked. A structure in which the memory cell arrays 120 are stacked, that is, a structure including all the memory cells arranged three-dimensionally is referred to as a three-dimensional memory cell array or a stacked-layer memory cell array in some cases.

Here, uppermost memory cells 111t each include a capacitor 113t. One terminal of the capacitor 113t is electrically connected to an electrode 122t. The electrode 122t is electrically connected to each of the capacitors 113t of the plurality of memory cells 111t.

The electrode 122t is provided to cover the plurality of memory cells 111 included in the memory device 110. In other words, the electrode 122t is provided to cover the top surface of the three-dimensional memory cell array. Furthermore, a fixed potential or a ground potential is preferably supplied to the electrode 122t. Accordingly, the electrode 122t functions as a protective film (also referred to as an electrostatic shielding film) that can block electrical noise input from the outside and protect the memory device 110 from the noise. With the electrode 122t, the memory device 110 can have high reliability.

Here, the electrode 122t preferably constitutes a part of the capacitor 113t. FIG. 1B is a schematic diagram obtained by extracting a part of the memory device 110.

The capacitor 113 included in the memory cell 111 includes an electrode 121 and an electrode 122. The electrode 121 is electrically connected to one of a source and a drain of the transistor 112. A fixed potential or a ground potential (here, a ground potential) is supplied to the electrode 122. A gate of the transistor 112 is electrically connected to a wiring WL functioning as a selection signal line (also referred to as a word line), and the other of the source and the drain of the transistor 112 is electrically connected to a wiring BL functioning as a data line (also referred to as a bit line).

In the same level (the memory cell array 120), a pair of memory cells 111 arranged bilaterally symmetrically are connected to one wiring BL. Thus, the number of memory cells 111 connected to one wiring BL is twice as large as the number of stacked memory cell arrays 120.

In the uppermost memory cell 111t, the capacitor 113t includes the electrode 121 and the electrode 122t. The electrode 122t serves as one electrode of at least two capacitors 113t. The electrode 122t is provided to cover the transistors 112, the wirings WL, and the wiring BL.

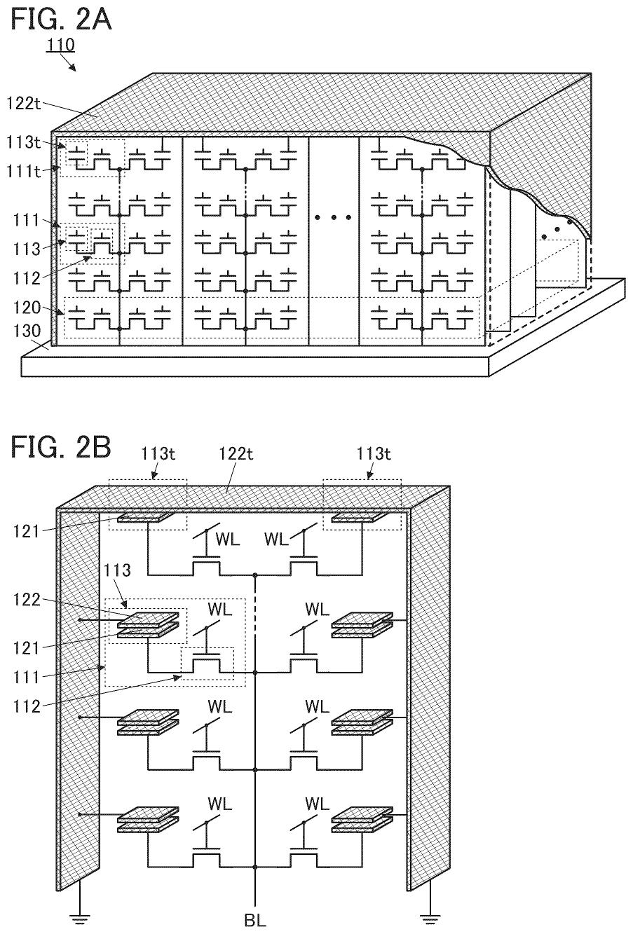

The electrode 122t is preferably provided not only above but also on a side of the three-dimensional memory cell array. FIG. 2A and FIG. 2B each illustrate an example of the electrode 122t with a different shape.

In FIG. 2A, the electrode 122t is provided to cover not only the top surface but also the side surfaces of the three-dimensional memory cell array in which a plurality of memory cell arrays 120 are stacked. Here, as the number of stacked memory cell arrays 120 increases, the aspect ratio (the ratio of the height to the length in the lateral direction or the depth direction) of the three-dimensional memory cell array increases, and thus the three-dimensional memory cell array is easily influenced by external electrical noise not only from the top surface but also from the side surfaces. Accordingly, the electrode 122t is preferably provided to cover the side surfaces of the three-dimensional memory cell array.

Although part of the electrode 122t is cut out for easy description in FIG. 2A and FIG. 2B, the electrode 122t is preferably provided to cover all surfaces other than the bottom surface of the three-dimensional memory cell array. In other words, the electrode 122t is preferably provided to cover all the side surfaces and the top surface of the three-dimensional memory cell array.

Furthermore, a side portion of the electrode 122t preferably reaches the substrate 130. In that case, part of the electrode 122t is preferably electrically connected to a wiring provided on the substrate 130. Accordingly, a fixed potential or a ground potential can be directly supplied from the substrate 130 to the electrode 122t.

As illustrated in FIG. 2B, it is preferable that the electrode 122 of the capacitor 113 in each memory cell be electrically connected to the electrode 122t and be supplied with a fixed potential or a ground potential (here, a ground potential) through the electrode 122t. This eliminates the need for a connection electrode (also referred to as a via hole) for supplying a potential from the substrate 130 to the electrode 122, whereby the manufacturing process can be simplified and the chip area can be reduced.

Next, a more specific example of the memory device of one embodiment of the present invention will be described.

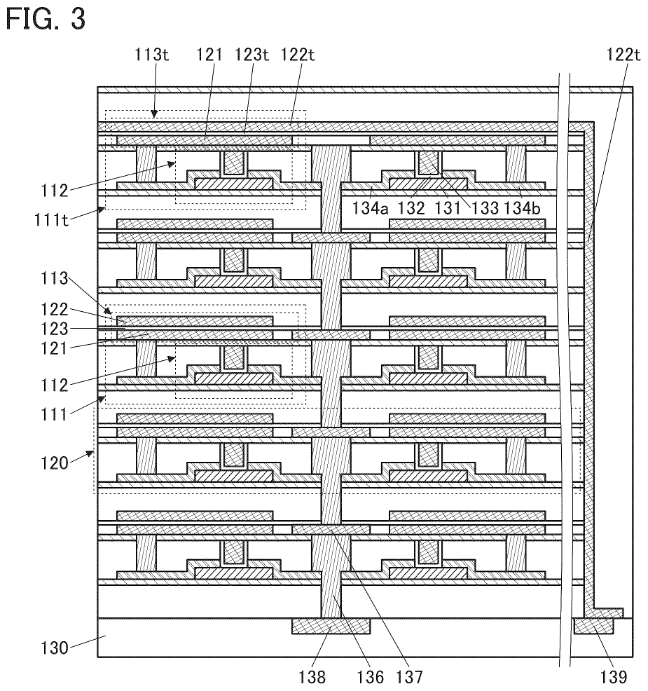

FIG. 3 illustrates a schematic cross-sectional view of the memory device. FIG. 3 illustrates a cross section of the case where five memory cell arrays 120 are stacked as an example.

The transistor 112 includes a semiconductor layer 131, a gate insulating layer 132, a gate electrode 133, and a pair of electrodes (an electrode 134a and an electrode 134b). The transistor that can be used in the memory device will be described in detail in a later embodiment. The electrode 134a functions as one of a source and a drain of the transistor 112, and the electrode 134b functions as the other of the source and the drain of the transistor 112.

A plurality of conductive layers 136 electrically connected to the stacked transistors 112 are provided to be stacked in the height direction. The stack of the conductive layers 136 can be referred to as a through electrode, a connection electrode, a plug, or the like. The conductive layer 136 is electrically connected to the electrode 134a of each transistor. The lowermost conductive layer 136 is electrically connected to a wiring 138 provided on the substrate 130. In FIG. 3, between two conductive layers 136 adjacent to each other in the height direction, a conductive layer 137 obtained by processing the same conductive film as the electrode 121 is provided. That is, the conductive layer 136 and the conductive layer 137 are alternately connected to each other.

The electrode 134b of the transistor 112 is electrically connected to the electrode 121 of the capacitor 113 or the capacitor 113t.

The capacitor 113 includes the electrode 121, the electrode 122, and an insulating layer 123 functioning as a dielectric and located between the electrodes. The capacitor 113t includes the electrode 121, the electrode 122t, and an insulating layer 123t. The insulating layer 123t and the electrode 122t are shared by the capacitors 113t of the memory cells 111t. The capacitor 113 and the capacitor 113t form what is called a parallel plate capacitor. The insulating layer 123t and the electrode 122t each include a portion overlapping with the electrode 121, a portion overlapping with the transistor 112, and a portion overlapping with the conductive layer 136.

Here, the electrode 122 is provided to overlap with the semiconductor layer 131 of the transistor 112 in the memory cell located thereabove, in which case the electrode 122 may also serve as a second gate electrode (a back gate electrode) of the transistor 112. Since a fixed potential or a ground potential is supplied to the electrode 122, using such an electrode as the back gate of the transistor 112 can stabilize the electrical characteristics such as the threshold voltage of the transistor 112.

On the right side in FIG. 3, a state in which the electrode 122t covers the side surface of the three-dimensional memory cell array is illustrated. The electrode 122t is electrically connected to a wiring 139 provided on the substrate 130. The wiring 139 is a wiring to which a ground potential or a fixed potential is supplied, for example.

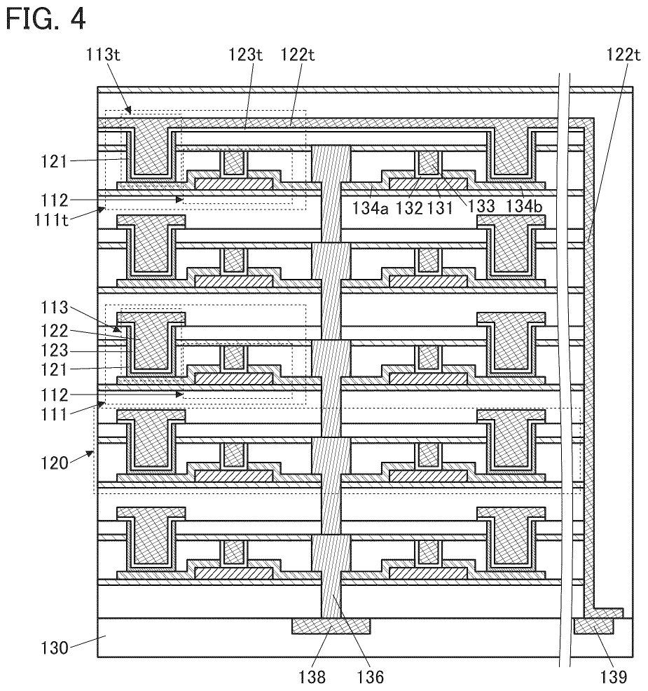

FIG. 4 illustrates an example in which the capacitor 113 and the capacitor 113t have structures different from those in FIG. 3.

An opening portion is provided in an interlayer insulating film to reach the electrode 134b of the transistor 112, and the electrode 121 and the insulating layer 123 (or the insulating layer 123t) are stacked along the sidewalls of the opening portion and the top surface of the electrode 134b. The electrode 122 (or the electrode 122t) is provided over the insulating layer 123 (or the insulating layer 123t) to fill the opening portion. In other words, it can be said that the top surface of the electrode 121 includes a depressed portion, and the electrode 122 includes a protruding portion engaging with the top surface of the electrode 121. The capacitor 113 and the capacitor 113t each having such a structure can be referred to as a trench-type capacitor or a trench capacitor. The capacitance value per area of the trench capacitor can be larger than that of a parallel plate capacitor, and thus the trench capacitor is suitable for reduction in area and high integration.

FIG. 4 illustrates an example in which the conductive layers 136 adjacent to each other in the vertical direction (the height direction) are directly connected to each other.

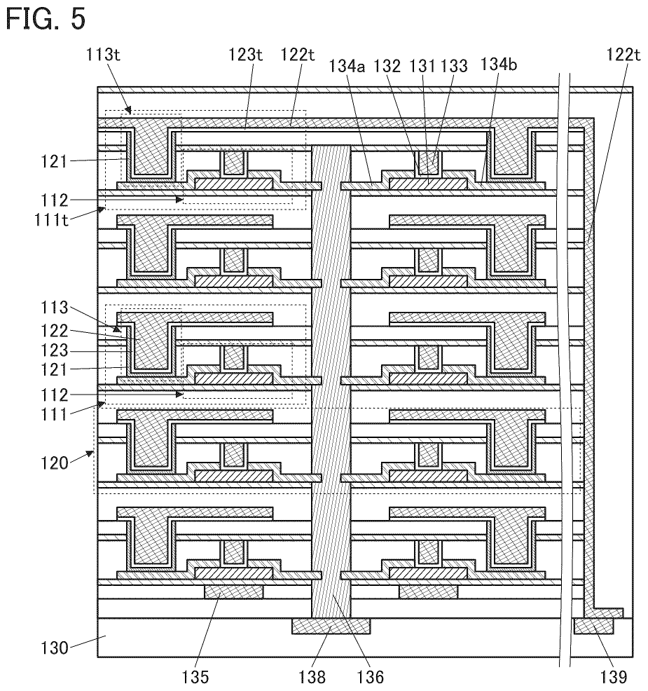

FIG. 5 illustrates a structure of a case where the electrode 122 also serves as the back gate of the transistor 112. The electrode 122 includes a portion overlapping with the semiconductor layer 131 included in the transistor 112 thereabove. Furthermore, FIG. 5 illustrates an example in which the transistor 112 in the lowermost memory cell array 120 is provided with a conductive layer 135 functioning as a back gate. As the electrode 122, the conductive layer 135 is supplied with a fixed potential or a ground potential.

FIG. 5 illustrates an example in which a through electrode is formed of one conductive layer 136. That is, an opening reaching the wiring 138 is provided to penetrate the stack of the memory cell arrays and the conductive layer 136 is embedded in the opening. Such a structure is preferable because the number of formation steps of the through electrode can be reduced.

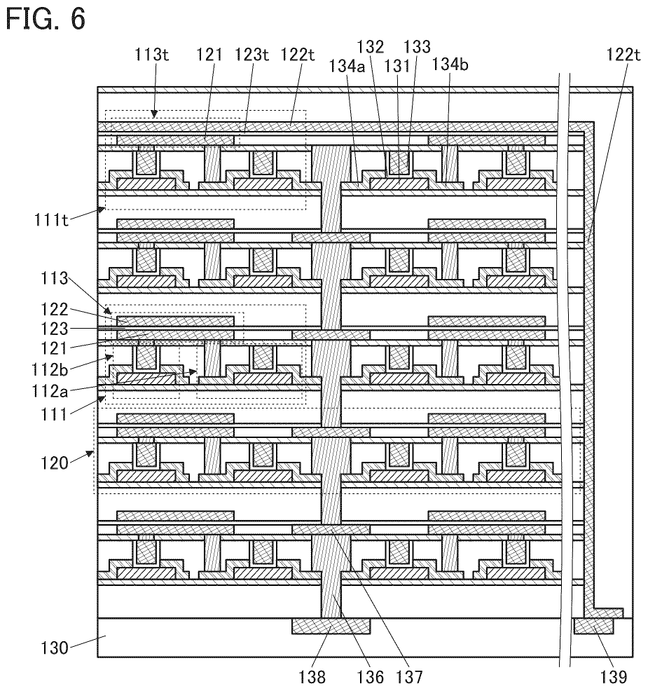

FIG. 6 illustrates an example in which the memory cell 111 and the memory cell 111t each include two transistors (a transistor 112a and a transistor 112b). Each of the transistor 112a and the transistor 112b has a structure similar to that of the transistor 112.

One of a source and a drain (the electrode 134a) of the transistor 112a is electrically connected to the conductive layer 136, and the other (the electrode 134b) of the transistor 112a is electrically connected to the electrode 121 of the capacitor 113 through a plug. Furthermore, a gate of the transistor 112b (the gate electrode 133) is electrically connected to the electrode 121 through another plug. That is, it can be said that the other of the source and the drain of the transistor 112a and the gate of the transistor 112b are electrically connected to each other through one electrode of the capacitor 113.

Next, structures of memory cells that can each be used in the memory device of one embodiment of the present invention will be described.

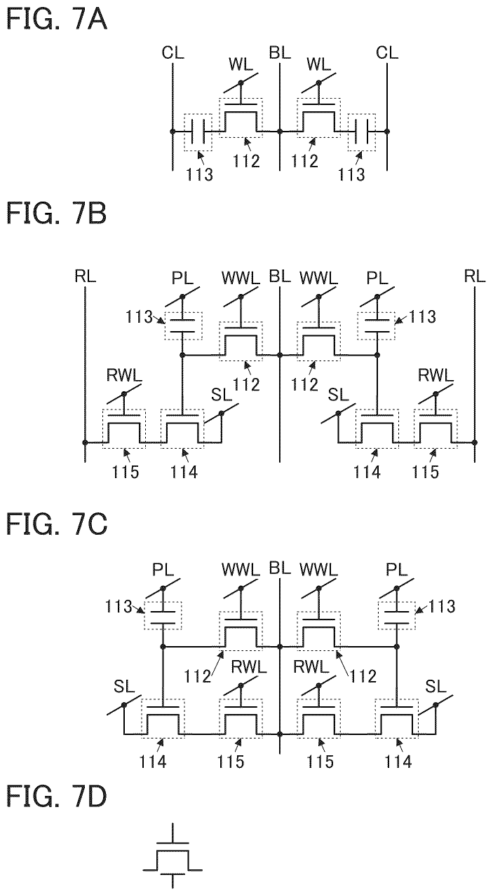

FIG. 7A, FIG. 7B, and FIG. 7C are each a circuit diagram in which two memory cells are connected bilaterally symmetrically.

FIG. 7A illustrates an example of a case where one memory cell includes one transistor 112 and one capacitor 113. Each memory cell is connected to the wiring BL, the wiring WL, and a wiring CL. The wiring BL functions as a bit line, and the wiring WL functions as a word line. The wiring CL is supplied with a fixed potential or a ground potential.

In FIG. 7A, the gate of the transistor 112 is electrically connected to the wiring WL, one of the source and the drain of the transistor 112 is electrically connected to the wiring BL, and the other thereof is electrically connected to one electrode of the capacitor 113. The other electrode of the capacitor 113 is electrically connected to the wiring CL.

FIG. 7B has a structure in which two transistors (a transistor 114 and a transistor 115) are added to each memory cell in FIG. 7A. The wiring BL, a wiring WWL, a wiring PL, a wiring SL, a wiring RWL, and a wiring RL are connected to each memory cell illustrated in FIG. 7B. The wiring WWL and the wiring RWL function as word lines. One of the wiring RL and the wiring SL is electrically connected to a read circuit, and the other thereof is supplied with a fixed potential or a signal. The wiring PL is supplied with a fixed potential or a ground potential.

The gate of the transistor 112 is electrically connected to the wiring WWL, one of the source and the drain of the transistor 112 is electrically connected to the wiring BL, and the other thereof is electrically connected to one electrode of the capacitor 113 and a gate of the transistor 114. The other electrode of the capacitor 113 is electrically connected to the wiring PL. One of a source and a drain of the transistor 114 is electrically connected to the wiring SL, and the other thereof is electrically connected to one of a source and a drain of the transistor 115. A gate of the transistor 115 is electrically connected to the wiring RWL, and the other of the source and the drain of the transistor 115 is electrically connected to the wiring RL.

Note that in the case of the structure illustrated in FIG. 7B, the transistor 115 is not necessarily provided when not needed. In that case, the other of the source and the drain of the transistor 114 can be electrically connected to the wiring RL. In the case where the transistor 115 is not provided, a potential supplied to the wiring PL is controlled so that the transistor 114 is not brought into a conduction state in the memory cell in which reading is not performed.

The transistor 112 in FIG. 7B corresponds to, for example, the transistor 112a in FIG. 6, and the transistor 114 in FIG. 7B corresponds to the transistor 112b in FIG. 6.

FIG. 7C is a modification example of FIG. 7B. In FIG. 7C, the wiring BL also serves as the wiring RL. That is, the other of the source and the drain of the transistor 115 is electrically connected to the wiring BL. Such a structure can reduce the number of wirings, thereby enabling high integration.

Here, a transistor including a back gate can be used as each of the transistors illustrated in FIG. 7A to FIG. 7C. FIG. 7D illustrates a transistor including a back gate. The back gate may be supplied with a fixed potential, a ground potential, a signal for controlling the threshold voltage of the transistor, or a signal supplied to the gate.

In the memory device of one embodiment of the present invention, the conductive film supplied with a fixed potential is provided to cover the memory cell array; thus, data change or the like due to the influence of electrical noise from the outside is inhibited, so that a highly reliable memory device can be achieved. With the structure in which the electrode of the capacitor element included in the memory cell also serves as the conductive film, a highly reliable memory device can be achieved while an increase in cost is suppressed. Furthermore, when an increase in the number of cells per area is achieved by stacking a plurality of memory cell arrays, the side surfaces can be covered with the conductive film even when the aspect ratio of the stacked-layer structure is high; thus, the memory device with both high integration and high reliability can be achieved.

At least part of this embodiment can be implemented in combination with the other embodiments described in this specification as appropriate.

### Embodiment 2

In this embodiment, a semiconductor device of one embodiment of the present invention will be described with reference to drawings. The semiconductor device described below as an example can be used as a memory device.

### <Structure Example of Semiconductor Device>

Structure examples of the semiconductor device of one embodiment of the present invention will be described below.

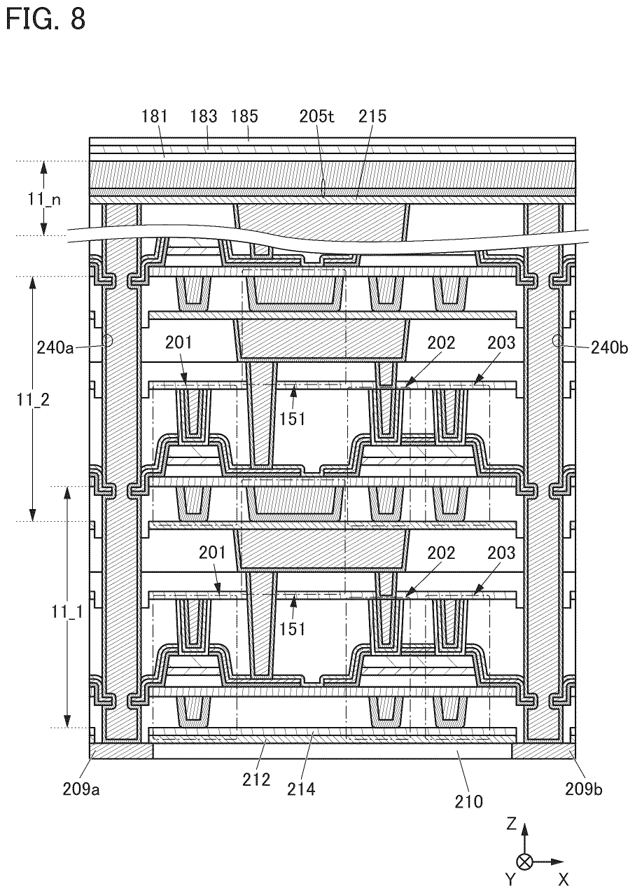

FIG. 8 is a cross-sectional view illustrating a structure example of the semiconductor device of one embodiment of the present invention. The semiconductor device illustrated in FIG. 8 includes an insulator 210 over a substrate (not illustrated), a conductor 209a and a conductor 209b embedded in the insulator 210, an insulator 212 over the insulator 210, an insulator 214 over the insulator 212, n (n is an integer greater than or equal to 2) memory layers 11 over the insulator 214, a conductor 240a and a conductor 240b that are provided to extend in the Z direction and penetrate the n memory layers 11 and are electrically connected to the conductor 209a and the conductor 209b, respectively, an insulator 181 over the memory layer 11_n, an insulator 183 over the insulator 181 and the conductor 240, and an insulator 185 over the insulator 183. Note that components included in the semiconductor device of this embodiment may each have either a single-layer structure or a stacked-layer structure.

In the following description of matters common to components distinguished from each other using letters of the alphabet, reference numerals without the letters of the alphabet are sometimes used. For example, in the case where matters common to the conductor 209a and the conductor 209b are described, the term “conductor 209” is used in some cases.

The memory layer 11_1 to the memory layer 11_n are each provided with a memory cell array including a plurality of memory cells. The memory cells each include a transistor 201, a transistor 202, a transistor 203, and a capacitor 151. The conductor 240a includes a region functioning as a write bit line, and the conductor 240b includes a region functioning as a read bit line.

In this specification and the like, a direction parallel to a channel length direction of a transistor illustrated is referred to as an X direction, and a direction parallel to a channel width direction of a transistor illustrated is referred to as a Y direction. The X direction and the Y direction can be perpendicular to each other. Furthermore, a direction perpendicular to both the X direction and the Y direction, i.e., a direction perpendicular to the XY plane, is referred to as a Z direction. The X direction and the Y direction can each be a direction parallel to the substrate surface, and the Z direction can be a direction perpendicular to the substrate surface, for example.

The conductor 209a and the conductor 209b each function as a wiring, an electrode, a terminal, or part of a circuit element such as a switch, a transistor, a capacitor, an inductor, a resistor, or a diode.

FIG. 8 illustrates, among the n memory layers 11, the memory layer 11_1 that is the lowest layer, the memory layer 11_2 over the memory layer 11_1, and the memory layer 11_n that is the uppermost layer.

The conductor 209a and the conductor 209b are electrically connected to driver circuits for driving the memory cells provided in the memory layers 11. The driver circuits are provided below the conductor 209a and the conductor 209b. Increasing the number of stacked memory layers 11 (the value of n) can increase the memory capacity of the memory device without an increase in the area occupied by the memory cells. Accordingly, the occupation area per bit is reduced, so that the semiconductor device can have a small size and large memory capacity.

The transistor 201, the transistor 202, and the transistor 203 are provided over the insulator 214. Here, the transistor 202 and the transistor 203 share some layers. The capacitor 151 is provided above the transistor 201 to the transistor 203.

FIG. 8 also illustrates a conductor 205t and an insulator 215, which function as an upper electrode and a dielectric layer of the capacitor 151, respectively, in the memory layer 11_n that is the uppermost layer. The conductor 205t and the insulator 215 are continuously provided across the region where the memory cell array is provided. The conductor 205t and the insulator 215 each include a region overlapping with the transistor 201, the transistor 202, the transistor 203, the capacitor 151, the conductor 240a, the conductor 240b, and the like positioned below the conductor 205t and the insulator 215.

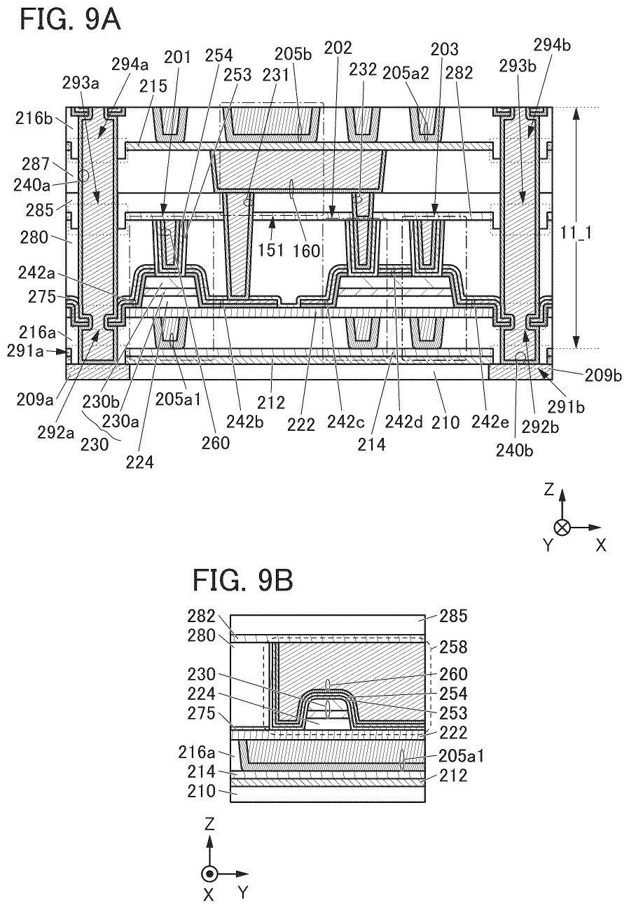

FIG. 9A is a cross-sectional view illustrating structure examples of the conductor 209a, the conductor 209b, the insulator 210, the insulator 212, the insulator 214, and the memory layer 11_1. As illustrated in FIG. 9A, an insulator 282 is provided over the transistor 201 to the transistor 203, and the capacitor 151 is provided over the insulator 282.

The transistor 201, the transistor 202, and the transistor 203 each include a conductor 205a1 over the insulator 214, an insulator 222 over the conductor 205a1, an insulator 224 over the insulator 222, a metal oxide 230 (a metal oxide 230a and a metal oxide 230b) over the insulator 224, a conductor 242 covering parts of the side surfaces of the insulator 224 and parts of the top surface and the side surfaces of the metal oxide 230, an insulator 253 over the metal oxide 230, an insulator 254 over the insulator 253, and a conductor 260 over the insulator 254. Here, the transistor 201 includes a conductor 242a and a conductor 242b as the conductor 242, the transistor 202 includes a conductor 242c and a conductor 242d as the conductor 242, and the transistor 203 includes the conductor 242d and a conductor 242e as the conductor 242. The transistor 202 and the transistor 203 share the metal oxide 230 and the conductor 242d.

An insulator 216a provided with an opening is provided over the insulator 214, and the conductor 205a1 is embedded in the opening. The insulator 222 is provided over the conductor 205a1 and the insulator 216a. An insulator 275 is provided over the conductor 242a to the conductor 242e, and an insulator 280 is provided over the insulator 275. The insulator 253, the insulator 254, and the conductor 260 are embedded in an opening provided in the insulator 280 and the insulator 275. The insulator 282 is provided over the insulator 280 and the conductor 260. The conductor 205a1 can include a region in contact with the side surface of the insulator 216a. The insulator 253 can include a region in contact with at least parts of the side surface of the conductor 242, the side surface of the insulator 275, and the side surface of the insulator 280.

The metal oxide 230 includes a region functioning as a channel formation region of the transistor 201, the transistor 202, or the transistor 203. Note that for the transistor 201, the transistor 202, and the transistor 203, a semiconductor such as single crystal silicon, polycrystalline silicon, or amorphous silicon may be used instead of the metal oxide 230; for example, low-temperature polysilicon (LTPS) may be used.

The conductor 242a includes a region functioning as one of a source electrode and a drain electrode of the transistor 201. The conductor 242b includes a region functioning as the other of the source electrode and the drain electrode of the transistor 201. The conductor 242c includes a region functioning as one of a source electrode and a drain electrode of the transistor 202. The conductor 242d includes a region functioning as the other of the source electrode and the drain electrode of the transistor 202 and a region functioning as one of a source electrode and a drain electrode of the transistor 203. The conductor 242e includes a region functioning as the other of the source electrode and the drain electrode of the transistor 203.

The conductor 260 includes a region functioning as a first gate electrode of the transistor 201, the transistor 202, or the transistor 203. The insulator 253 and the insulator 254 each include a region functioning as a first gate insulator of the transistor 201, the transistor 202, or the transistor 203.

The conductor 205a1 includes a region functioning as a second gate electrode of the transistor 201, the transistor 202, or the transistor 203. The insulator 222 includes a region functioning as a second gate insulator of the transistor 201, a region functioning as a second gate insulator of the transistor 202, and a region functioning as a second gate insulator of the transistor 203. The insulator 224 includes a region functioning as the second gate insulator of the transistor 201, the transistor 202, or the transistor 203.

In this specification and the like, the first gate electrode can be referred to as a front gate electrode or simply as a gate electrode, and the second gate electrode can be referred to as a back gate electrode. Note that the first gate electrode may be referred to as a back gate electrode, and the second gate electrode may be referred to as a front gate electrode or simply as a gate electrode.

The transistor 202 and the transistor 203 are adjacent to each other and share the metal oxide 230 and the conductor 242d as described above. Thus, the two transistors (the transistor 202 and the transistor 203) can be formed in an area smaller than the area of two transistors (for example, in the area of one and a half transistors). This enables the transistors to be arranged at high density as compared with the case where the transistor 202 and the transistor 203 do not share the metal oxide 230 and the conductor 242d; hence, high integration in the semiconductor device can be achieved.

The conductor 242d is placed in a region between the conductor 260 included in the transistor 202 and the conductor 260 included in the transistor 203. Thus, an n-type region (a low-resistance region) can be formed in a region of the metal oxide 230 that overlaps with the conductor 242d. Specifically, the n-type region can be formed in a region of the metal oxide 230b that overlaps with the conductor 242d. Moreover, current can flow between the transistor 202 and the transistor 203 through the conductor 242d. Thus, the resistance component between the transistor 202 and the transistor 203 can be significantly reduced as compared with a structure in which two transistors using silicon in their semiconductor layers where channels are formed (also referred to as Si transistors) are connected in series.

The capacitor 151 includes a conductor 160 over the insulator 282, the insulator 215 over the conductor 160, and a conductor 205b over the insulator 215.

An insulator 285 is provided over the insulator 282, and an insulator 287 is provided over the insulator 285. An opening is provided in the insulator 287, and the conductor 160 is embedded in the opening. The insulator 215 is provided over the conductor 160 and the insulator 287. An insulator 216b provided with a plurality of openings is provided over the insulator 215, and a conductor 205a2, the conductor 205b, and the like are embedded in the openings. The conductor 160 can include a region in contact with at least parts of the top surface of the insulator 285 and the side surface of the insulator 287. The conductor 205a2 and the conductor 205b can each include a region in contact with the side surface of the insulator 216b.

Hereinafter, in the case where matters common to the conductor 205a1 and the conductor 205a2 are described, the term “conductor 205a” is used in some cases. In addition, in the case where matters common to the conductor 205a and the conductor 205b are described, the term “conductor 205” is used in some cases.

The conductor 160 includes a region functioning as one electrode (also referred to as a lower electrode) of the capacitor 151. The insulator 215 includes a region functioning as a dielectric of the capacitor 151. The conductor 205b includes a region functioning as the other electrode (also referred to as an upper electrode) of the capacitor 151. The capacitor 151 forms a MIM (Metal-Insulator-Metal) capacitor.

An opening reaching the conductor 242b is provided in the insulator 280, the insulator 282, and the insulator 285, and a conductor 231 is embedded in the opening. An opening reaching the conductor 260 included in the transistor 202 is provided in the insulator 282 and the insulator 285, and a conductor 232 is provided in the opening. The conductor 242b and the conductor 160 are electrically connected to each other through the conductor 231. The conductor 260 included in the transistor 202 and the conductor 160 are electrically connected to each other through the conductor 232. In this manner, the conductor 242b including the region functioning as the other of the source electrode and the drain electrode of the transistor 201 is electrically connected to the conductor 260 including the region functioning as the gate electrode of the transistor 202 through the conductor 231, the conductor 160, and the conductor 232. The conductor 160 includes a region in contact with the top surface of the conductor 231 and a region in contact with the top surface of the conductor 232.

The conductor 242a, the conductor 242b, the conductor 242c, and the conductor 242e extend beyond the metal oxide 230 functioning as a semiconductor layer and cover parts of the top surface and the side surfaces of the metal oxide 230. Thus, the conductor 242a, the conductor 242b, the conductor 242c, and the conductor 242e also function as wirings. The conductor 240a including the region functioning as a write bit line is provided to include a region in contact with parts of the top surface, the side surface, and the bottom surface of the conductor 242a, for example. The conductor 240b including the region functioning as a read bit line is provided to include a region in contact with parts of the top surface, the side surface, and the bottom surface of the conductor 242e. Note that the conductor 242d can also function as a wiring. Another conductor can also function as a wiring in some cases.

Since the conductor 240a includes the region in contact with parts of the top surface, the side surface, and the bottom surface of the conductor 242a and the conductor 240b includes the region in contact with parts of the top surface, the side surface, and the bottom surface of the conductor 242e, a connection electrode does not need to be provided additionally; thus, the area occupied by the memory cell array can be reduced. In addition, the integration degree of the memory cells can be increased and the memory capacity can be increased. Note that the conductor 240a includes a region in contact with two or more of the top surface, the side surface, and the bottom surface of the conductor 242a, and the conductor 240b includes a region in contact with two or more of the top surface, the side surface, and the bottom surface of the conductor 242e. When the conductor 240a is in contact with two or more surfaces of the conductor 242a, the contact resistance between the conductor 240a and the conductor 242a can be reduced as compared with the case where the conductor 240a is in contact with only one surface of the conductor 242a, for example. When the conductor 240b is in contact with two or more surfaces of the conductor 242e, the contact resistance between the conductor 240b and the conductor 242e can be reduced as compared with the case where the conductor 240b is in contact with only one surface of the conductor 242e, for example.

Here. an opening 291a including a region overlapping with the conductor 209a and an opening 291b including a region overlapping with the conductor 209b are provided in the insulator 212 and the insulator 214. An opening 292a including a region overlapping with the conductor 209a and the opening 291a and an opening 292b including a region overlapping with the conductor 209b and the opening 291b are provided in the insulator 222. An opening 293a including a region overlapping with the conductor 209a, the opening 291a, and the opening 292a and an opening 293b including a region overlapping with the conductor 209b, the opening 291b, and the opening 292b are provided in the insulator 282. An opening 294a including a region overlapping with the conductor 209a, the opening 291a, the opening 292a, and the opening 293a and an opening 294b including a region overlapping with the conductor 209b, the opening 291b, the opening 292b, and the opening 293b are provided in the insulator 215. The conductor 240a is provided in the opening 291a to the opening 294a, and the conductor 240a is provided in the opening 291b to the opening 294b, Note that the opening 291a and the opening 291b are not necessarily provided in the insulator 212. In that case, a structure can be obtained in which the side surface of the insulator 212 is not aligned with the side surface of the insulator 214, for example, The side surface of the insulator 212 can include a region in contact with the side surface of the conductor 240a, and the side surface of the insulator 212 can include a region in contact the side surface of the conductor 240b, for example.

In each of the opening 291a and the opening 291b, the insulator 216a covers the side surface of the insulator 212 and the side surface of the insulator 214. The conductor 242a covers the side surface of the insulator 222 in the opening 292a, and the conductor 242e covers the side surface of the insulator 222 in the opening 292b. In each of the opening 293a and the opening 293b, the insulator 285 covers the side surface of the insulator 282. In each of the opening 294a and the opening 294b, the insulator 216b covers the side surface of the insulator 215.

Accordingly, the insulator 216a can be regarded as being provided to cover parts of the top surface and the side surfaces of the insulator 214. In addition, the conductor 242a and the conductor 242e can be regarded as being provided to cover parts of the top surface and the side surfaces of the insulator 222. Moreover, the insulator 285 can be regarded as being provided to cover parts of the top surface and the side surfaces of the insulator 282, and the insulator 216b can be regarded as being provided to cover parts of the top surface and the side surfaces of the insulator 215.

In the semiconductor device of one embodiment of the present invention having the above structure, the conductor 240a and the conductor 240b are each provided to include regions in contact with at least parts of the side surface of the insulator 212, the side surface of the insulator 216a, the side surface of the insulator 275, the side surface of the insulator 285, the side surface of the insulator 287, and the side surface of the insulator 216b. As described above, the conductor 240a is provided to include the region in contact with the side surface of the conductor 242a, and the conductor 240a and the conductor 240b are each provided to include the region in contact with the side surface of the conductor 242e. Furthermore, the conductor 240a and the conductor 240b are provided so as not to be in contact with the insulator 212, the insulator 214, the insulator 282, or the insulator 215.

When the semiconductor device of one embodiment of the present invention has the above structure, the insulator 212, the insulator 214, the insulator 282, and the insulator 215 do not need to be processed at the time of providing an opening that penetrates the memory layer 11_1 to the memory layer 11_n and reaches the conductor 209a after the memory layer 11_n illustrated in FIG. 8 is formed. Thus, the opening can be formed under one condition even when the insulator 212, the insulator 214, the insulator 282, and the insulator 215 are formed using materials that are easily processed under different conditions from materials for the other insulators. This can widen the range of choices for materials that can be used for the insulators. Note that the conductor 240a and the conductor 240b can each be formed by embedding a conductive film in the opening.

FIG. 9B is a cross-sectional view illustrating a structure example of the transistor illustrated in FIG. 9A in the channel width direction, i.e., in the Y direction.

In the example illustrated in FIG. 9B, the insulator 212 is provided over the insulator 210, the insulator 214 is provided over the insulator 212, the insulator 216a is provided over the insulator 214, and the conductor 205a1 is provided in the opening provided in the insulator 216a. The insulator 222 is provided over the conductor 205a1 and the insulator 216a, the insulator 224 and the insulator 275 are provided over the insulator 222, and the metal oxide 230 is provided over the insulator 224. The side surfaces of the insulator 224 and the top surface and the side surfaces of the metal oxide 230 are covered with the insulator 253, the insulator 254, and the conductor 260. The insulator 253, the insulator 254, and the conductor 260 are provided in an opening 258 formed in the insulator 280 over the insulator 275. The insulator 282 is provided over the insulator 253, the insulator 254, the conductor 260, and the insulator 280, and the insulator 285 is provided over the insulator 282.

Here, the conductor 260 including the region functioning as the first gate electrode can be regarded as covering not only the top surface but also the side surfaces of the metal oxide 230.

In this specification and the like, a transistor structure in which a channel formation region is electrically surrounded by at least the electric field of the first gate electrode is referred to as a surrounded channel (S-channel) structure. The S-channel structure disclosed in this specification and the like has a structure that is different from a Fin-type structure and a planar structure. The S-channel structure disclosed in this specification and the like can be regarded as a kind of the Fin-type structure. Note that in this specification and the like, the Fin-type structure refers to a structure in which a gate electrode is placed to cover at least two or more surfaces (specifically, two surfaces, three surfaces, or four surfaces) of a channel. With the use of the Fin-type structure and the S-channel structure, a transistor with high resistance to a short-channel effect, i.e., a transistor in which a short-channel effect is unlikely to occur, can be obtained.

When the transistor included in the semiconductor device of this embodiment has the above-described S-channel structure, the channel formation region can be electrically surrounded. Since the S-channel structure is a structure with the electrically surrounded channel formation region, the S-channel structure is, in a sense, equivalent to a GAA (Gate All Around) structure or an LGAA (Lateral Gate All Around) structure. In the transistor having the S-channel structure, the GAA structure, or the LGAA structure, the channel formation region that is formed at the interface between an oxide and a gate insulator or in the vicinity of the interface can be the entire bulk of the metal oxide. Accordingly, the density of current flowing through the transistor can be improved, which can be expected to improve the on-state current of the transistor or increase the field-effect mobility of the transistor.

Although FIG. 9B illustrates a transistor with the S-channel structure as the transistor, the semiconductor device of one embodiment of the present invention is not limited thereto. For example, a transistor structure that can be used in one embodiment of the present invention may be one or more selected from the planar structure, the Fin-type structure, and the GAA structure.

Note that a cross-sectional shape of the metal oxide 230 may have a curved surface between its side surface and top surface as illustrated in FIG. 9B. Thus, coverage with a film formed over the metal oxide 230 can be improved.

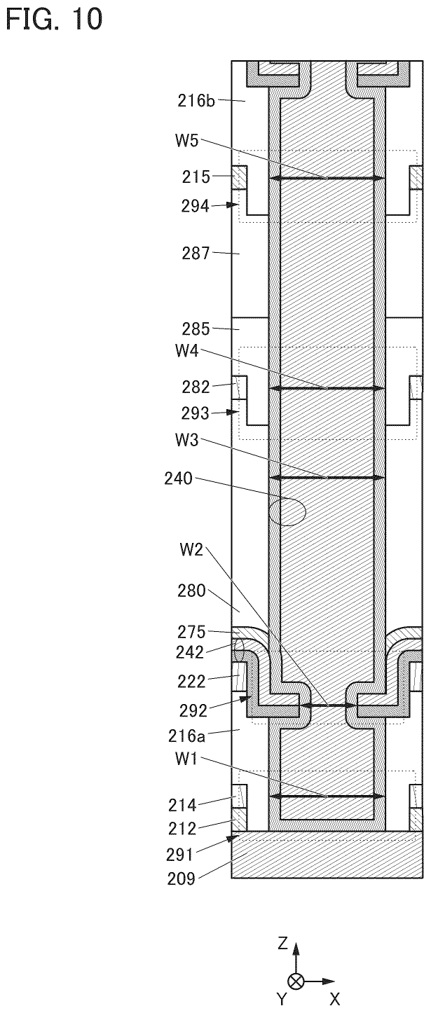

FIG. 10 is an enlarged view of part of the conductor 240 and its peripheral region. In the conductor 240 in FIG. 10, the width of a region in contact with the side surface of the insulator 216a is referred to as a width W1, the width of a region in contact with the side surface of the conductor 242 is referred to as a width W2, the width of a region in contact with the side surface of the insulator 280 is referred to as a width W3, the width of a region in contact with the side surface of the insulator 285 is referred to as a width W4, and the width of a region in contact with the side surface of the insulator 216b is referred to as a width W5.

As illustrated in FIG. 10, at least some of the width W1, the width W3, the width W4, and the width W5 are preferably larger than the width W2. In this structure, the conductor 240 is in contact with at least parts of the top surface and the side surface of the conductor 242. Thus, the area of a region where the conductor 240 is in contact with the conductor 242 can be increased. Note that in this specification and the like, the contact between the conductor 240 and the conductor 242 is sometimes referred to as a top side contact. As illustrated in FIG. 10, the conductor 240 may be in contact with part of the bottom surface of the conductor 242. With such a structure, the area of the region where the conductor 240 is in contact with the conductor 242 can be further increased.

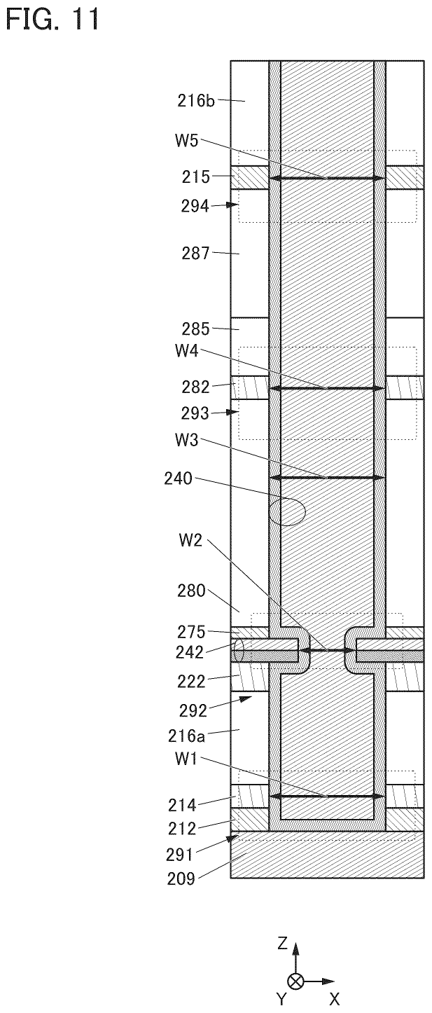

FIG. 11 illustrates a modification example of the structure illustrated in FIG. 10, in which at least part of the side surface of the insulator 282 and at least part of the side surface of the insulator 215 are in contact with the conductor 240. In the conductor 240 in FIG. 11, the width of a region in contact with the side surface of the insulator 212 or the insulator 214 is referred to as the width W1, the width of a region in contact with the side surface of the conductor 242 is referred to as the width W2, the width of a region in contact with the side surface of the insulator 280 is referred to as the width W3, the width of a region in contact with the side surface of the insulator 282 is referred to as the width W4, and the width of a region in contact with the side surface of the insulator 215 is referred to as the width W5.

FIG. 11 illustrates an example in which the width W1, the width W3, the width W4, and the width W5 are equal or substantially equal to each other. In the example illustrated in FIG. 11, it can be said that in the cross-sectional view, the end portions of the insulator 212 and the insulator 214 and the end portion of the insulator 216a are aligned or substantially aligned with each other, the end portion of the insulator 282 and the end portion of the insulator 285 are aligned or substantially aligned with each other, and the end portion of the insulator 215 and the end portion of the insulator 216b are aligned or substantially aligned with each other. It is thus possible to obtain the structure in which the side surfaces of the insulator 212 and the insulator 214 are not covered with the insulator 216a, the side surface of the insulator 282 is not covered with the insulator 285, and the side surface of the insulator 215 is not covered with the insulator 216b. In the example illustrated in FIG. 11, the end portion of the insulator 212, the end portion of the insulator 214, the end portion of the insulator 216a, the end portion of the insulator 280, the end portion of the insulator 282, the end portion of the insulator 285, the end portion of the insulator 287, the end portion of the insulator 215, and the end portion of the insulator 216b can be aligned or substantially aligned with each other in the cross-sectional view. Note that the width W1, the width W3, the width W4, and the width W5 can each be larger than the width W2.

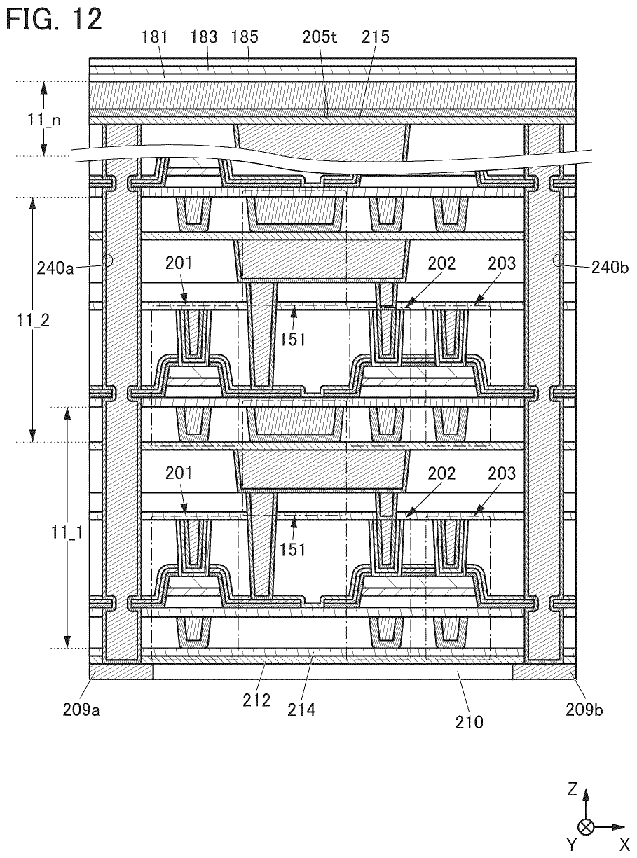

FIG. 12 is a cross-sectional view illustrating structure examples of the memory layer 11_1 to the memory layer 11_n each having the structure illustrated in FIG. 11 and is a modification example of the structure illustrated in FIG. 8.

Next, the transistors included in the semiconductor device of this embodiment will be described in detail.

The metal oxide 230 preferably includes the metal oxide 230a over the insulator 224 and the metal oxide 230b over the metal oxide 230a. Including the metal oxide 230a under the metal oxide 230b makes it possible to inhibit diffusion of impurities into the metal oxide 230b from components formed below the metal oxide 230a.

Although an example in which the metal oxide 230 has a two-layer structure of the metal oxide 230a and the metal oxide 230b is described in this embodiment, the present invention is not limited thereto. For example, the metal oxide 230 may have a single-layer structure of the metal oxide 230b or a stacked-layer structure of three or more layers.

The metal oxide 230b includes a channel formation region of each transistor and a source region and a drain region provided to sandwich the channel formation region. At least part of the channel formation region overlaps with the conductor 260. The source region overlaps with one of a pair of conductors 242, and the drain region overlaps with the other of the pair of conductors 242.

The channel formation region has a smaller amount of oxygen vacancies or a lower impurity concentration than the source region and the drain region, and thus is a high-resistance region with a low carrier concentration. Thus, the channel formation region can be regarded as being i-type (intrinsic) or substantially i-type.

The source region and the drain region have a large amount of oxygen vacancies or a high concentration of an impurity such as hydrogen, nitrogen, or a metal element, and thus are each a low-resistance region with a high carrier concentration. In other words, the source region and the drain region are each an n-type region (a low-resistance region) having a higher carrier concentration than the channel formation region.

Note that the carrier concentration of the channel formation region is preferably lower than or equal to 1×10¹⁸ cm⁻³, lower than 1×10¹⁷ cm⁻³, lower than 1×10¹⁶ cm⁻³, lower than 1×10¹⁵ cm⁻³, lower than 1×10¹⁴ cm⁻³, lower than 1×10¹³ cm⁻³, lower than 1×10¹² cm⁻³, lower than 1×10¹¹ cm⁻³, or lower than 1×10¹⁰ cm⁻³. The lower limit of the carrier concentration of the channel formation region is not particularly limited and can be, for example, 1 × 10-9 cm⁻³.

In order to reduce the carrier concentration in the metal oxide 230b, the impurity concentration in the metal oxide 230b is reduced so that the density of defect states is reduced. In this specification and the like, a state with a low impurity concentration and a low density of defect states is referred to as a highly purified intrinsic or substantially highly purified intrinsic state. Note that an oxide semiconductor (or a metal oxide) having a low carrier concentration may be referred to as a highly purified intrinsic or substantially highly purified intrinsic oxide semiconductor (or a metal oxide).

In order to obtain stable electrical characteristics of the transistor, reducing the impurity concentration in the metal oxide 230b is effective. In order to reduce the impurity concentration in the metal oxide 230b, it is preferable that the impurity concentration in an adjacent film be also reduced. Examples of impurities include hydrogen, nitrogen, an alkali metal, an alkaline earth metal, iron, nickel, and silicon. Note that an impurity in the metal oxide 230b refers to, for example, an element other than the main components of the metal oxide 230b. For example, an element with a concentration lower than 0.1 atomic % can be regarded as an impurity.

Note that the channel formation region, the source region, and the drain region may each be formed not only in the metal oxide 230b but also in the metal oxide 230a.

In the metal oxide 230, the boundary of each region is difficult to detect clearly in some cases. The concentrations of a metal element and impurity elements such as hydrogen and nitrogen, which are detected in each region, may be not only gradually changed between the regions but also continuously changed in each region. That is, the region closer to the channel formation region may have lower concentrations of a metal element and impurity elements such as hydrogen and nitrogen.

A metal oxide functioning as a semiconductor (hereinafter, also referred to as an oxide semiconductor) is preferably used as the metal oxide 230.

The metal oxide functioning as a semiconductor preferably has a band gap of 2 eV or more, further preferably 2.5 eV or more. With the use of a metal oxide having a wide band gap, the off-state current of the transistor can be reduced.

As the metal oxide 230, a metal oxide such as indium oxide, gallium oxide, or zinc oxide is preferably used, for example. Alternatively, as the metal oxide 230, a metal oxide containing two or three selected from indium, an element M, and zinc is preferably used, for example. Note that the element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium. In particular, the element M is preferably one or more kinds selected from aluminum, gallium, yttrium, and tin. Note that a metal oxide containing indium, the element M, and zinc is referred to as In—M—Zn oxide in some cases.

The metal oxide 230 preferably has a stacked-layer structure of a plurality of oxide layers with different chemical compositions. For example, the atomic ratio of the element M to In in the metal oxide used as the metal oxide 230a is preferably greater than the atomic ratio of the element M to In in the metal oxide used as the metal oxide 230b. With this structure, impurities and oxygen can be inhibited from diffusing into the metal oxide 230b from the components formed below the metal oxide 230a.

Furthermore, the atomic ratio of In to the element M in the metal oxide used as the metal oxide 230b is preferably greater than the atomic ratio of In to the element M in the metal oxide used as the metal oxide 230a. With this structure, the transistor can have a high on-state current and high frequency characteristics.

When the metal oxide 230a and the metal oxide 230b contain a common element as the main component besides oxygen, the density of defect states at an interface between the metal oxide 230a and the metal oxide 230b can be decreased. The density of defect states at the interface between the metal oxide 230a and the metal oxide 230b can be decreased. Thus, the influence of interface scattering on carrier conduction is small, and the transistor can have a high on-state current and high frequency characteristics.

Specifically, as the metal oxide 230a, a metal oxide with a composition of In:M:Zn=1:3:4 [atomic ratio] or in the neighborhood thereof or a composition of In:M:Zn=1:1:0.5 [atomic ratio] or in the neighborhood thereof can be used. As the metal oxide 230b, a metal oxide with a composition of In:M:Zn=1:1:1 [atomic ratio] or in the neighborhood thereof, a composition of In:M:Zn=1:1:1.2 [atomic ratio] or in the neighborhood thereof, a composition of In:M:Zn=1:1:2 [atomic ratio] or in the neighborhood thereof, or a composition of In:M:Zn=4:2:3 [atomic ratio] or in the neighborhood thereof can be used. Note that a composition in the neighborhood includes the range of ±30% of an intended atomic ratio. Gallium is preferably used as the element M. In the case where a single layer of the metal oxide 230b is provided as the metal oxide 230, a metal oxide that can be used as the metal oxide 230a may be used as the metal oxide 230b.

Note that a metal oxide in which the atomic ratio of In to the element M is greater than that in the metal oxide 230b may be used as the metal oxide 230a, or a metal oxide in which the atomic ratio of the element M to In is greater than that in the metal oxide 230a may be used as the metal oxide 230b. With this structure, the reliability can be improved.

When the metal oxide is deposited by a sputtering method, the above atomic ratio is not limited to the atomic ratio of the deposited metal oxide and may be the atomic ratio of a sputtering target used for depositing the metal oxide.

The metal oxide 230b preferably has crystallinity. It is particularly preferable to use a CAAC-OS (c-axis aligned crystalline oxide semiconductor) as the metal oxide 230b.

The CAAC-OS is a metal oxide having a dense structure with high crystallinity and small amounts of impurities and defects (e.g., oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. When the density of the CAAC-OS is increased in such a manner, diffusion of impurities or oxygen in the CAAC-OS can be further reduced.

A clear crystal grain boundary is difficult to observe in the CAAC-OS; thus, it can be said that a reduction in electron mobility due to the crystal grain boundary is less likely to occur. Thus, a metal oxide including the CAAC-OS is physically stable. Therefore, the metal oxide including the CAAC-OS is resistant to heat and has high reliability.

When an oxide having crystallinity, such as the CAAC-OS, is used as the metal oxide 230b, oxygen extraction from the metal oxide 230b by the source electrode or the drain electrode can be inhibited. This can reduce oxygen extraction from the metal oxide 230b even when heat treatment is performed; thus, the transistor is stable with respect to high temperatures in a manufacturing process (what is called thermal budget).

A transistor using an oxide semiconductor is likely to have its electrical characteristics changed by impurities and oxygen vacancies in a region where a channel is formed in the oxide semiconductor, which might reduce the reliability. In some cases, a defect that is an oxygen vacancy into which hydrogen in the vicinity of the oxygen vacancy has entered (hereinafter, also referred to as V_{O}H) is formed, which generates an electron serving as a carrier. Therefore, when the region where a channel is formed in the oxide semiconductor includes oxygen vacancies, the transistor is likely to have normally-on characteristics (characteristics with which, even when no voltage is applied to the gate electrode, the channel exists and current flows through the transistor). Therefore, impurities, oxygen vacancies, and V_{O}H are preferably reduced as much as possible in the region where a channel is formed in the oxide semiconductor. In other words, the region where a channel is formed in the oxide semiconductor is preferably an i-type (intrinsic) or substantially i-type region with a reduced carrier concentration.

As a countermeasure against the above, an insulator containing oxygen that is released by heating (hereinafter, also referred to as excess oxygen) is provided in the vicinity of the oxide semiconductor and heat treatment is performed, so that oxygen can be supplied from the insulator to the oxide semiconductor to reduce oxygen vacancies and V_{O}H. However, supply of an excess amount of oxygen to the source region or the drain region might cause a decrease in the on-state current or field-effect mobility of the transistor. Furthermore, a variation in the amount of oxygen supplied to the source region or the drain region in the substrate plane leads to a variation in characteristics of the semiconductor device including the transistor. When oxygen supplied from the insulator to the oxide semiconductor diffuses into conductors such as the gate electrode, the source electrode, and the drain electrode, the conductors might be oxidized and the conductivity might be impaired, for example, so that the electrical characteristics and reliability of the transistor might be adversely affected.

Accordingly, in the oxide semiconductor, the channel formation region is preferably an i-type or substantially i-type region with a reduced carrier concentration, whereas the source region and the drain region are preferably n-type regions with high carrier concentrations. That is, the amounts of oxygen vacancies and V_{O}H in the channel formation region of the oxide semiconductor are preferably reduced. Supply of an excess amount of oxygen to the source region and the drain region and excessive reduction in the amount of V_{O}H in the source region and the drain region are preferably inhibited. Furthermore, a structure is preferable in which a reduction in the conductivity of the conductor 260, the conductor 242, and the like is inhibited. For example, a structure is preferable in which oxidation of the conductor 260, the conductor 242, and the like is inhibited. Note that hydrogen in the oxide semiconductor can form V_{O}H; thus, the hydrogen concentration needs to be reduced in order to reduce the amount of V_{O}H.

The insulator 253 in contact with the channel formation region of the metal oxide 230b preferably has a function of capturing and fixing hydrogen. Thus, the hydrogen concentration in the channel formation region of the metal oxide 230b can be reduced. Accordingly, V_{O}H in the channel formation region can be reduced, so that the channel formation region can be an i-type or substantially i-type region.

Examples of an insulator having a function of capturing and fixing hydrogen include a metal oxide having an amorphous structure. As the insulator 253, for example, a metal oxide, such as magnesium oxide or an oxide containing one or both of aluminum and hafnium, is preferably used. In such a metal oxide having an amorphous structure, an oxygen atom has a dangling bond and sometimes has a property of capturing or fixing hydrogen with the dangling bond. That is, the metal oxide having an amorphous structure has high capability of capturing or fixing hydrogen.

A high dielectric constant (high-k) material is preferably used for the insulator 253. An example of the high-k material is an oxide containing one or both of aluminum and hafnium. With the use of the high-k material for the insulator 253, a gate potential applied during the operation of the transistor can be reduced while the physical thickness of the gate insulator is maintained. In addition, the equivalent oxide thickness (EOT) of the insulator functioning as the gate insulator can be reduced.

As described above, for the insulator 253, an oxide containing one or both of aluminum and hafnium is preferably used, an oxide containing one or both of aluminum and hafnium and having an amorphous structure is further preferably used, and hafnium oxide having an amorphous structure is still further preferably used. In this embodiment, hafnium oxide is used for the insulator 253. In that case, the insulator 253 is an insulator that contains at least oxygen and hafnium. The hafnium oxide has an amorphous structure. In that case, the insulator 253 has an amorphous structure.

Alternatively, as the insulator 253, an insulator having a thermally stable structure, such as silicon oxide or silicon oxynitride, may be used. For example, the insulator 253 may have a stacked-layer structure including aluminum oxide and silicon oxide or silicon oxynitride over the aluminum oxide. For another example, the insulator 253 may have a stacked-layer structure including aluminum oxide, silicon oxide or silicon oxynitride over the aluminum oxide, and hafnium oxide over the silicon oxide or silicon oxynitride.

In order to inhibit oxidation of the conductor 242 and the conductor 260, a barrier insulator against oxygen is preferably provided in the vicinity of each of the conductor 242 and the conductor 260. In the semiconductor device described in this embodiment, the insulator corresponds to the insulator 253, the insulator 254, and the insulator 275, for example.

Note that in this specification and the like, a barrier insulator refers to an insulator having a barrier property. A barrier property in this specification and the like means a function of inhibiting diffusion of a targeted substance (also referred to as having low permeability). Alternatively, the barrier property means a function of capturing and fixing (also referred to as gettering) a targeted substance.

Examples of the barrier insulator against oxygen include an oxide containing one or both of aluminum and hafnium, magnesium oxide, gallium oxide, indium gallium zinc oxide, silicon nitride, and silicon nitride oxide. Examples of the oxide containing one or both of aluminum and hafnium include aluminum oxide, hafnium oxide, an oxide containing aluminum and hafnium (hafnium aluminate), and an oxide containing hafnium and silicon (hafnium silicate). For example, each of the insulator 253, the insulator 254, and the insulator 275 preferably has a single-layer structure or a stacked-layer structure of the barrier insulator against oxygen.

It is preferable that oxygen be less likely to pass through the insulator 253 than at least the insulator 280. The insulator 253 includes a region in contact with the side surface of the conductor 242. When the insulator 253 has a barrier property against oxygen, oxidation of the side surface of the conductor 242 and formation of an oxide film on the side surface can be inhibited. Accordingly, a decrease in the on-state current or field-effect mobility of the transistor can be inhibited.

The insulator 253 is provided in contact with the top surface and the side surface of the metal oxide 230b, the side surface of the metal oxide 230a, the side surface of the insulator 224, and the top surface of the insulator 222. When the insulator 253 has a barrier property against oxygen, release of oxygen from the channel formation region of the metal oxide 230b caused by heat treatment can be inhibited, for example. This can reduce formation of oxygen vacancies in the metal oxide 230a and the metal oxide 230b.

Even when an excess amount of oxygen is contained in the insulator 280, in contrast, oxygen can be inhibited from being excessively supplied to the metal oxide 230a and the metal oxide 230b. Thus, it is possible to inhibit excessive oxidation of the source region and the drain region and a decrease in the on-state current or field-effect mobility of the transistor.

The insulator 254 preferably has a barrier property against oxygen. The insulator 254 is provided between the conductor 260 and the channel formation region of the metal oxide 230 and between the insulator 280 and the conductor 260. Such a structure can inhibit diffusion of oxygen contained in the channel formation region of the metal oxide 230 into the conductor 260 and formation of oxygen vacancies in the channel formation region of the metal oxide 230. Oxygen contained in the metal oxide 230 and oxygen contained in the insulator 280 can be inhibited from diffusing into the conductor 260 and oxidizing the conductor 260. It is preferable that oxygen be less likely to pass through the insulator 254 than at least the insulator 280. For example, silicon nitride is preferably used for the insulator 254. In that case, the insulator 254 is an insulator that contains at least nitrogen and silicon.

The insulator 254 preferably has a barrier property against hydrogen. Accordingly, diffusion of impurities contained in the conductor 260, such as hydrogen, into the metal oxide 230b can be prevented.

The insulator 275 preferably has a barrier property against oxygen. The insulator 275 is provided between the insulator 280 and the conductor 242. With this structure, oxygen contained in the insulator 280 can be inhibited from diffusing into the conductor 242. Thus, the conductor 242 can be inhibited from being oxidized by oxygen contained in the insulator 280, so that an increase in resistivity and a reduction in on-state current can be inhibited. It is preferable that oxygen be less likely to pass through the insulator 275 than at least the insulator 280. For example, silicon nitride is preferably used for the insulator 275. In that case, the insulator 275 is an insulator that contains at least nitrogen and silicon.

In order to inhibit a reduction in hydrogen concentration in the source region and the drain region in the metal oxide 230, a barrier insulator against hydrogen is preferably provided in the vicinity of each of the source region and the drain region. In the semiconductor device described in this embodiment, the barrier insulator against hydrogen is, for example, the insulator 275.

Examples of the barrier insulator against hydrogen include oxides such as aluminum oxide, hafnium oxide, and tantalum oxide and nitrides such as silicon nitride. For example, the insulator 275 preferably has a single-layer structure or a stacked-layer structure of the above barrier insulator against hydrogen.

The insulator 275 preferably has a barrier property against hydrogen. When the insulator 275 has a barrier property against hydrogen, capturing and fixing of hydrogen in the source region and the drain region by the insulator 253 can be inhibited. Thus, the source region and the drain region can be n-type regions.

With the above structure, the channel formation region can be an i-type or substantially i-type region, and the source region and the drain region can be n-type regions; thus, a semiconductor device with excellent electrical characteristics can be provided. The semiconductor device with the above structure can have excellent electrical characteristics even when scaled down or highly integrated. Scaling down of the transistor can improve the high-frequency characteristics. Specifically, the cutoff frequency can be improved.

The insulator 253 and the insulator 254 each function as part of a gate insulator. The insulator 253 and the insulator 254 are provided together with the conductor 260 in an opening formed in the insulator 280 and the like. The thickness of the insulator 253 and the thickness of the insulator 254 are preferably small for scaling down of the transistor. The thickness of the insulator 253 is preferably greater than or equal to 0.1 nm and less than or equal to 5.0 nm, further preferably greater than or equal to 0.5 nm and less than or equal to 5.0 nm, still further preferably greater than or equal to 1.0 nm and less than 5.0 nm, yet still further preferably greater than or equal to 1.0 nm and less than or equal to 3.0 nm. The thickness of the insulator 254 is preferably greater than or equal to 0.1 nm and less than or equal to 5.0 nm, further preferably greater than or equal to 0.5 nm and less than or equal to 3.0 nm, still further preferably greater than or equal to 1.0 nm and less than or equal to 3.0 nm. Note that at least part of each of the insulator 253 and the insulator 254 includes a region having the above-described thickness.

To form the insulator 253 having a small thickness as described above, an atomic layer deposition (ALD) method is preferably used for deposition. Examples of an ALD method include a thermal ALD method, in which a precursor and a reactant react with each other only by a thermal energy, and a PEALD (Plasma Enhanced ALD) method, in which a reactant excited by plasma is used. The use of plasma in a PEALD method is sometimes preferable because deposition at a lower temperature is possible.

An ALD method, which enables atomic layers to be deposited one by one, has advantages such as formation of an extremely thin film, film formation on a component with a high aspect ratio, formation of a film with a small number of defects such as pinholes, film formation with excellent coverage, and low-temperature film formation. Therefore, the insulator 253 can be formed on the side surface of the opening portion formed in the insulator 280 and the like, the side end portion of the conductor 242, and the like, with a small thickness like the above-described thickness and good coverage.

Note that some of precursors usable in an ALD method contain carbon, for example. Thus, in some cases, a film provided by an ALD method contains impurities such as carbon in a larger amount than a film provided by another deposition method. Note that impurities can be quantified by secondary ion mass spectrometry (SIMS), X-ray photoelectron spectroscopy (XPS), or auger electron spectroscopy (AES).

For example, silicon nitride deposited by a PEALD method can be used for the insulator 254.

Note that when an insulator having a function of inhibiting passage of oxygen and impurities such as hydrogen, e.g., hafnium oxide, is used as the insulator 253, the insulator 253 can also have the function of the insulator 254. In such a case, the structure without the insulator 254 enables simplification of the manufacturing process and the improvement in productivity of the semiconductor device.

In addition to the above structure, the semiconductor device of this embodiment preferably has a structure in which hydrogen is inhibited from entering the transistor. For example, an insulator having a function of inhibiting diffusion of hydrogen is preferably provided to cover one or both of the upper portion and the lower portion of the transistor. In the semiconductor device described in this embodiment, the insulator is, for example, the insulator 212.

As the insulator 212, an insulator having a function of inhibiting diffusion of hydrogen is preferably used. This can inhibit diffusion of hydrogen into the transistor from below the insulator 212. As the insulator 212, the above-described insulator that can be used as the insulator 275 can be used.

One or more of the insulator 212, the insulator 214, and the insulator 282 preferably function as a barrier insulating film, which inhibits diffusion of impurities such as water and hydrogen into the transistor from the substrate side or from above the transistor. Thus, one or more of the insulator 212, the insulator 214, and the insulator 282 preferably contain an insulating material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), or a copper atom (an insulating material through which the impurities are less likely to pass). Alternatively, it is preferable to contain an insulating material having a function of inhibiting diffusion of oxygen (e.g., at least one of an oxygen atom, an oxygen molecule, and the like) (an insulating material through which the oxygen is less likely to pass).

The insulator 212, the insulator 214, and the insulator 282 each preferably include an insulator having a function of inhibiting diffusion of oxygen and impurities such as water and hydrogen; for example, aluminum oxide, magnesium oxide, hafnium oxide, gallium oxide, indium gallium zinc oxide, silicon nitride, silicon nitride oxide, or the like can be used. For example, silicon nitride, which has a higher hydrogen barrier property, is preferably used for the insulator 212. For example, the insulator 212, the insulator 214, and the insulator 282 each preferably contain aluminum oxide, magnesium oxide, or the like, which has an excellent function of capturing and fixing hydrogen. Accordingly, impurities such as water and hydrogen can be inhibited from diffusing from the substrate side to the transistor side through the insulator 212 and the insulator 214. Furthermore, impurities such as water and hydrogen can be inhibited from diffusing to the transistor side from an interlayer insulating film and the like placed outside the insulator 282. Moreover, oxygen contained in the insulator 224 and the like can be inhibited from diffusing to the substrate side. In addition, oxygen contained in the insulator 280 and the like can be inhibited from diffusing to the components over the transistor through the insulator 282 and the like. In this manner, it is preferable that the transistor be surrounded by the insulators having a function of inhibiting diffusion of oxygen and impurities such as water and hydrogen.

The conductor 205a is placed to overlap with the metal oxide 230 and the conductor 260. Here, the conductor 205a is preferably provided to fill an opening portion formed in the insulator 216a. Part of the conductor 205a is embedded in the insulator 214 in some cases.

The conductor 205a may have either a single-layer structure or a stacked-layer structure. For example, FIG. 9A illustrates an example in which the conductor 205a has a two-layer stacked structure of a first conductor and a second conductor. The first conductor of the conductor 205a is provided in contact with the bottom surface and sidewall of the opening portion provided in the insulator 216a. The second conductor of the conductor 205a is provided to be embedded in a depressed portion formed in the first conductor of the conductor 205a. Here, the top surface of the second conductor of the conductor 205a is substantially level with the top surface of the first conductor of the conductor 205a and the top surface of the insulator 216a.

Here, the first conductor of the conductor 205a preferably contains a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), and a copper atom. Alternatively, it is preferable to contain a conductive material having a function of inhibiting diffusion of oxygen (e.g., at least one of an oxygen atom, an oxygen molecule, and the like).

When a conductive material having a function of inhibiting diffusion of hydrogen is used for the first conductor of the conductor 205a, impurities such as hydrogen contained in the second conductor of the conductor 205a can be prevented from diffusing into the metal oxide 230 through the insulator 216a, the insulator 224, and the like. When a conductive material having a function of inhibiting diffusion of oxygen is used for the first conductor of the conductor 205a, the conductivity of the second conductor of the conductor 205a can be inhibited from being lowered because of oxidation. Examples of the conductive material having a function of inhibiting diffusion of oxygen include titanium, titanium nitride, tantalum, tantalum nitride, ruthenium, and ruthenium oxide. The first conductor of the conductor 205a can have a single-layer structure or a stacked-layer structure of the above conductive material. For example, the first conductor of the conductor 205a preferably contains titanium nitride.

A conductive material containing tungsten, copper, or aluminum as its main component is preferably used for the second conductor of the conductor 205a. For example, the second conductor of the conductor 205a preferably contains tungsten.

The conductor 205a can function as the second gate electrode. In that case, by changing a potential applied to the conductor 205a not in conjunction with but independently of a potential applied to the conductor 260, the threshold voltage (Vth) of the transistor can be controlled. In particular, by applying a negative potential to the conductor 205a, Vth of the transistor can be higher, and its off-state current can be reduced. Thus, a drain current at the time when a potential applied to the conductor 260 is 0 V can be lower in the case where a negative potential is applied to the conductor 205a than in the case where the negative potential is not applied to the conductor 205a.

The electrical resistivity of the conductor 205a is designed in consideration of the potential applied to the conductor 205a, and the thickness of the conductor 205a is set in accordance with the electrical resistivity. The thickness of the insulator 216a is substantially equal to the thickness of the conductor 205a. Here, the conductor 205a and the insulator 216a are preferably as thin as possible in the allowable range of the design of the conductor 205a. When the thickness of the insulator 216a is reduced, the absolute amount of impurities such as hydrogen contained in the insulator 216a can be reduced, so that diffusion of the impurities into the metal oxide 230 can be inhibited.

The insulator 222 and the insulator 224 function as a gate insulator.

It is preferable that the insulator 222 have a function of inhibiting diffusion of hydrogen (e.g., at least one of a hydrogen atom, a hydrogen molecule, and the like). In addition, it is preferable that the insulator 222 have a function of inhibiting diffusion of oxygen (e.g., at least one of an oxygen atom, an oxygen molecule, and the like). For example, the insulator 222 preferably has a function of inhibiting diffusion of one or both of hydrogen and oxygen more than the insulator 224.

The insulator 222 preferably includes an insulator containing an oxide of one or both of aluminum and hafnium, which is an insulating material. For the insulator, aluminum oxide, hafnium oxide, an oxide containing aluminum and hafnium (hafnium aluminate), or the like is preferably used. Alternatively, an oxide containing hafnium and zirconium, e.g., a hafnium zirconium oxide, is preferably used. In the case where the insulator 222 is formed using such a material, the insulator 222 functions as a layer that inhibits release of oxygen from the metal oxide 230 to the substrate side and diffusion of impurities such as hydrogen from the periphery of the transistor into the metal oxide 230. Thus, providing the insulator 222 can inhibit diffusion of impurities such as hydrogen to the inside of the transistor and inhibit generation of oxygen vacancies in the metal oxide 230. Moreover, the first conductor of the conductor 205a can be inhibited from reacting with oxygen contained in the insulator 224 and the metal oxide 230.

Alternatively, aluminum oxide, bismuth oxide, germanium oxide, niobium oxide, silicon oxide, titanium oxide, tungsten oxide, yttrium oxide, or zirconium oxide may be added to the above insulators, for example. Alternatively, these insulators may be subjected to nitriding treatment. A stack of silicon oxide, silicon oxynitride, or silicon nitride over the above insulators may be used for the insulator 222.

For example, the insulator 222 may have a single-layer structure or a stacked-layer structure of an insulator(s) containing what is called a high-k material such as aluminum oxide, hafnium oxide, tantalum oxide, zirconium oxide, or hafnium zirconium oxide. As scaling down and high integration of transistors progress, a problem such as leakage current may arise because of a thinner gate insulator. When a high-k material is used for the insulator functioning as a gate insulator, a gate potential at the time of the operation of the transistor can be reduced while the physical thickness is maintained. Furthermore, a substance with a high dielectric constant such as lead zirconate titanate (PZT), strontium titanate (SrTiO₃), or (Ba,Sr)TiO₃ (BST) can be used for the insulator 222 in some cases.

The insulator 224 that is in contact with the metal oxide 230 preferably contains silicon oxide or silicon oxynitride, for example.

Note that the insulator 222 and the insulator 224 may each have a stacked-layer structure of two or more layers. In that case, without limitation to a stacked-layer structure formed of the same material, a stacked-layer structure formed of different materials may be employed.

A conductive material that is not easily oxidized or a conductive material having a function of inhibiting oxygen diffusion is preferably used for each of the conductor 242 and the conductor 260. Examples of the conductive material include a conductive material containing nitrogen and a conductive material containing oxygen. This can inhibit a reduction in the conductivity of the conductor 242 and the conductor 260. In the case where a conductive material containing metal and nitrogen is used for the conductor 242 and the conductor 260, the conductor 242 and the conductor 260 are conductors that contain at least metal and nitrogen.

The conductor 242 may have a single-layer structure or a stacked-layer structure. The conductor 260 may have a single-layer structure or a stacked-layer structure.

For example, the conductor 242 illustrated in FIG. 9A has a two-layer structure of a first conductor and a second conductor over the first conductor. In that case, for the first conductor of the conductor 242 in contact with the metal oxide 230b, it is preferable to use a conductive material that is not easily oxidized or a conductive material having a function of inhibiting oxygen diffusion. Thus, the conductivity of the conductor 242 can be inhibited from being reduced. For the first conductor of the conductor 242, a material that is likely to absorb (extract) hydrogen is preferably used, in which case the hydrogen concentration in the metal oxide 230 can be reduced.

The second conductor of the conductor 242 preferably has higher conductivity than the first conductor of the conductor 242. For example, the thickness of the second conductor of the conductor 242 is preferably larger than the thickness of the first conductor of the conductor 242.

For example, tantalum nitride or titanium nitride can be used for the first conductor of the conductor 242, and tungsten can be used for the second conductor of the conductor 242.

To inhibit a reduction in the conductivity of the conductor 242, an oxide having crystallinity, such as a CAAC-OS, is preferably used as the metal oxide 230b. Specifically, a metal oxide containing indium, zinc, and one or more selected from gallium, aluminum, and tin is preferably used. When a CAAC-OS is used, oxygen extraction from the metal oxide 230b by the conductor 242 can be inhibited. Furthermore, it is possible to inhibit a reduction in the conductivity of the conductor 242.

As the conductor 242, for example, a nitride containing tantalum, a nitride containing titanium, a nitride containing molybdenum, a nitride containing tungsten, a nitride containing tantalum and aluminum, or a nitride containing titanium and aluminum is preferably used. In one embodiment of the present invention, a nitride containing tantalum is particularly preferable. For another example, ruthenium oxide, ruthenium nitride, an oxide containing strontium and ruthenium, or an oxide containing lanthanum and nickel may be used. These materials are preferable because they are each a conductive material that is not easily oxidized or a material that maintains the conductivity even after absorbing oxygen.

Note that, for example, hydrogen contained in the metal oxide 230b diffuses into the conductor 242 in some cases. In particular, when a nitride containing tantalum is used for the conductor 242, for example, hydrogen contained in the metal oxide 230b is likely to diffuse into the conductor 242, and the diffused hydrogen is bonded to nitrogen contained in the conductor 242 in some cases. That is, hydrogen contained in the metal oxide 230b or the like is sometimes absorbed by the conductor 242, for example.

The conductor 260 is placed such that its top surface is substantially level with the uppermost portion of the insulator 254, the uppermost portion of the insulator 253, and the top surface of the insulator 280.

The conductor 260 functions as the first gate electrode of the transistor. The conductor 260 preferably includes a first conductor and a second conductor over the first conductor. For example, the first conductor of the conductor 260 is preferably placed to cover the bottom surface and the side surface of the second conductor of the conductor 260.

For example, the conductor 260 illustrated in FIG. 9A has a two-layer structure. In that case, for the first conductor of the conductor 260, it is preferable to use a conductive material that is not easily oxidized or a conductive material having a function of inhibiting oxygen diffusion.

For the first conductor of the conductor 260, it is preferable to use a conductive material having a function of inhibiting diffusion of impurities such as a hydrogen atom, a hydrogen molecule, a water molecule, a nitrogen atom, a nitrogen molecule, a nitrogen oxide molecule, and a copper atom. Alternatively, it is preferable to use a conductive material having a function of inhibiting diffusion of oxygen (e.g., at least one of an oxygen atom, an oxygen molecule, and the like).

In addition, when the first conductor of the conductor 260 has a function of inhibiting oxygen diffusion, for example, the conductivity of the second conductor of the conductor 260 can be inhibited from being lowered because of oxidation due to oxygen contained in the insulator 280. As the conductive material having a function of inhibiting oxygen diffusion, for example, titanium, titanium nitride, tantalum, tantalum nitride, ruthenium, or ruthenium oxide is preferably used.

As the conductor 260, a conductor having high conductivity is preferably used. For example, a conductive material containing tungsten, copper, or aluminum as its main component can be used for the second conductor of the conductor 260. The second conductor of the conductor 260 may have a stacked-layer structure; for example, a stacked-layer structure of the conductive material and titanium or titanium nitride may be employed.

In the transistor, the conductor 260 is formed in a self-aligned manner to fill the opening formed in the insulator 280, for example. The formation of the conductor 260 in this manner allows the conductor 260 to be placed properly in a region between the pair of conductors 242 without alignment.

The dielectric constant of each of the insulator 216a, the insulator 280, the insulator 285, the insulator 287, the insulator 216b, the insulator 181, and the insulator 185 is preferably lower than that of the insulator 214. When a material with a low dielectric constant is used for an interlayer film, parasitic capacitance generated between wirings can be reduced.

For example, the insulator 216a, the insulator 280, the insulator 285, the insulator 287, the insulator 216b, the insulator 181, and the insulator 185 each preferably contain one or more of silicon oxide, silicon oxynitride, silicon oxide to which fluorine is added, silicon oxide to which carbon is added, silicon oxide to which carbon and nitrogen are added, and porous silicon oxide.

In particular, silicon oxide and silicon oxynitride, which are thermally stable, are preferable. A material such as silicon oxide, silicon oxynitride, or porous silicon oxide is particularly preferably used, in which case a region containing oxygen released by heating can be easily formed.

The top surfaces of the insulator 216a, the insulator 280, the insulator 285, the insulator 287, the insulator 216b, the insulator 181, and the insulator 185 may be planarized.

The concentration of impurities such as water and hydrogen in the insulator 280 is preferably reduced. For example, the insulator 280 preferably contains an oxide containing silicon, such as silicon oxide or silicon oxynitride.

Note that in the opening portion of the insulator 280, the sidewall of the insulator 280 may be substantially perpendicular to the top surface of the insulator 222 or may have a tapered shape. The tapered sidewall can improve the coverage with the insulator 253 provided in the opening portion of the insulator 280, for example; as a result, the number of defects such as voids can be reduced.

Note that in this specification and the like, a tapered shape refers to a shape such that at least part of the side surface of a component is inclined with respect to a substrate surface or a formation surface. For example, a tapered shape preferably includes a region where the angle between the inclined side surface and the substrate surface or the formation surface (hereinafter, also referred to as a taper angle) is less than 90°. Note that the side surface of the component and the substrate surface are not necessarily completely flat and may be substantially flat with a slight curvature or substantially flat with slight unevenness.

For the conductor 160 and the conductor 205b included in the capacitor 151, any of the materials that can be used for the conductor 205a, the conductor 242, and the conductor 260 can be used. The conductor 160 and the conductor 205b are preferably formed by a deposition method that offers good coverage, such as an ALD method or a chemical vapor deposition (CVD) method.

The conductor 160 includes a first conductor and a second conductor over the first conductor. For example, titanium nitride deposited by an ALD method can be used for the first conductor of the conductor 160, and tungsten deposited by a CVD method can be used for the second conductor of the conductor 160. Note that in the case where the adhesion of tungsten to the insulator 282 is sufficiently high, a single-layer structure of tungsten deposited by a CVD method may be used for the conductor 160.

For the insulator 215 included in the capacitor 151, a high dielectric constant (high-k) material (a material with a high relative permittivity) is preferably used. The insulator 215 is preferably formed by a deposition method that offers good coverage, such as an ALD method or a CVD method.

Examples of insulators of the high dielectric constant (high-k) material include an oxide, an oxynitride, a nitride oxide, and a nitride containing one or more kinds of metal elements selected from aluminum, hafnium, zirconium, gallium, and the like. The above-described oxide, oxynitride, nitride oxide, and nitride may contain silicon. Stacked insulators formed of any of the above-described materials can also be used.

Examples of the insulators of the high dielectric constant (high-k) material include aluminum oxide, hafnium oxide, zirconium oxide, an oxide containing aluminum and hafnium, an oxynitride containing aluminum and hafnium, an oxide containing silicon and hafnium, an oxynitride containing silicon and hafnium, an oxide containing silicon and zirconium, an oxynitride containing silicon and zirconium, an oxide containing hafnium and zirconium, and an oxynitride containing hafnium and zirconium. Using such a high-k material allows the insulator 215 to be thick enough to inhibit leakage current and the capacitor 151 to have a sufficiently high capacitance.

It is preferable to use stacked insulators formed of any of the above-described materials, and it is preferable to use a stacked-layer structure of a high dielectric constant (high-k) material and a material having a higher dielectric strength than the high dielectric constant (high-k) material. As the insulator 215, an insulator in which zirconium oxide, aluminum oxide, and zirconium oxide are stacked in this order can be used, for example. For another example, an insulator in which zirconium oxide, aluminum oxide, zirconium oxide, and aluminum oxide are stacked in this order can be used. For another example, an insulating film in which hafnium zirconium oxide, aluminum oxide, hafnium zirconium oxide, and aluminum oxide are stacked in this order can be used. Using such stacked insulators with relatively high dielectric strength, such as aluminum oxide, can increase the dielectric strength and inhibit electrostatic breakdown of the capacitor 151.

The conductor 240 preferably has a stacked-layer structure of a first conductor and a second conductor. For example, as illustrated in FIG. 9A, the conductor 240 can have a structure in which the first conductor is provided in contact with an inner wall of the opening portion and the second conductor is provided on the inner side. The first conductor of the conductor 240) includes regions in contact with at least parts of the top surface of the conductor 209, the side surface of the insulator 212, the side surface of the insulator 216a, the top surface and the side surface of the conductor 242, the side surface of the insulator 280, the side surface of the insulator 285, the side surface of the insulator 287, and the side surface of the insulator 216b.

A conductive material having a function of inhibiting passage of impurities such as water and hydrogen is preferably used for the first conductor of the conductor 240. The first conductor of the conductor 240 can have a single-layer structure or a stacked-layer structure including one or more of tantalum, tantalum nitride, titanium, titanium nitride, ruthenium, and ruthenium oxide, for example. Thus, impurities such as water and hydrogen can be inhibited from entering the metal oxide 230 through the conductor 240.

The conductor 240 also functions as a wiring and thus is preferably formed using a conductor having high conductivity. For example, a conductive material containing tungsten, copper, or aluminum as its main component can be used for the second conductor of the conductor 240.

For example, it is preferable to use titanium nitride for the first conductor of the conductor 240 and tungsten for the second conductor of the conductor 240. In that case, the first conductor of the conductor 240 is a conductor that contains titanium and nitrogen, and the second conductor of the conductor 240 is a conductor that contains tungsten.

Note that the conductor 240 may have either a single-layer structure or a stacked-layer structure of three or more layers. Although FIG. 8 illustrates an example in which the top surface of the conductor 240 is level with the bottom surface of the insulator 215, the level of the top surface of the conductor 240 may be higher than the level of the bottom surface of the insulator 215, for example.

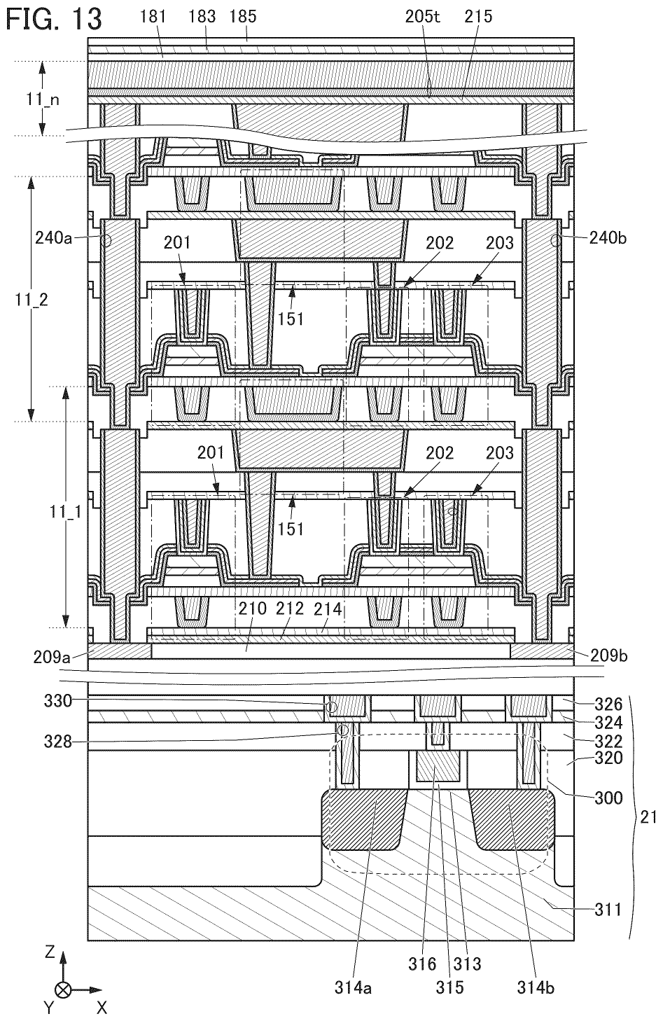

FIG. 13 is a cross-sectional view illustrating a structure example of the semiconductor device of one embodiment of the present invention. The semiconductor device illustrated in FIG. 13 is an example in which a layer including a transistor 300 is provided under the structure illustrated in FIG. 8, for example. The transistor 300 can be provided in a driver circuit of a memory cell formed above the insulator 210, for example. Note that the structure above the insulator 210 in FIG. 13 is similar to that in FIG. 8; thus, the detailed description thereof is omitted.

FIG. 13 illustrates an example of the transistor 300. The transistor 300 is provided on a substrate 311 and includes a conductor 316 functioning as a gate, an insulator 315 functioning as a gate insulator, a semiconductor region 313 including part of the substrate 311, and a low-resistance region 314a and a low-resistance region 314b functioning as a source region and a drain region. The transistor 300 may be either a p-channel transistor or an n-channel transistor. As the substrate 311, a single crystal silicon substrate can be used, for example.

Here, in the transistor 300 illustrated in FIG. 13, the semiconductor region 313 (part of the substrate 311) in which a channel is formed has a protruding shape. The conductor 316 is provided to cover the side surface and the top surface of the semiconductor region 313 with the insulator 315 therebetween. Note that a material adjusting the work function may be used for the conductor 316. Such a transistor 300 is also referred to as a FIN-type transistor because it utilizes a protruding portion of a semiconductor substrate. Note that an insulator functioning as a mask for forming the protruding portion may be included in contact with an upper portion of the protruding portion. Furthermore, although the case where the protruding portion is formed by processing part of the semiconductor substrate is described here, a semiconductor film having a protruding shape may be formed by processing an SOI (Silicon on Insulator) substrate.

Note that the transistor 300 illustrated in FIG. 13 is an example and the structure is not limited thereto; an appropriate transistor can be used in accordance with a circuit structure or a driving method.

A wiring layer provided with an interlayer film, a wiring, a plug, and the like may be provided between the components. A plurality of wiring layers can be provided in accordance with design. Furthermore, in this specification and the like, a wiring and a plug electrically connected to the wiring may be a single component. That is, part of a conductor functions as a wiring in some cases and part of the conductor functions as a plug in other cases.

For example, an insulator 320, an insulator 322, an insulator 324, and an insulator 326 are stacked in this order over the transistor 300 as an interlayer film. A conductor 328 or the like is embedded in the insulator 320 and the insulator 322. A conductor 330 or the like is embedded in the insulator 324 and the insulator 326. Note that the conductor 328 and the conductor 330 function as a contact plug or a wiring.

The insulators functioning as the interlayer film may also function as a planarization film that covers an uneven shape thereunder. For example, the top surface of the insulator 322 may be planarized by planarization treatment using a chemical mechanical polishing (CMP) method or the like to have improved planarity.

FIG. 13 illustrates an example in which the conductor 240a and the conductor 240b are formed for each memory layer 11. In the structure illustrated in FIG. 13, n conductors 240a are connected in the height direction to form a through electrode. Similarly, n conductors 240b are connected in the height direction. The conductors 240a, each of which is in contact with the top surface and the side surface of the conductor 242, are electrically connected to each other, and the conductors 240b, each of which in contact with the top surface and the side surface of the conductor 242, are electrically connected to each other.

FIG. 13 also illustrates the conductor 205t and the insulator 215, which function as an upper electrode and a dielectric layer of the capacitor 151, respectively, in the memory layer 11_n that is the uppermost layer. The conductor 205t and the insulator 215 are continuously provided across the region where the memory cell array is provided. The conductor 205t and the insulator 215 each include a region overlapping with the transistor 201, the transistor 202, the transistor 203, the capacitor 151, each of the conductors 240a, each of the conductors 240b, and the like positioned below the conductor 205t and the insulator 215.

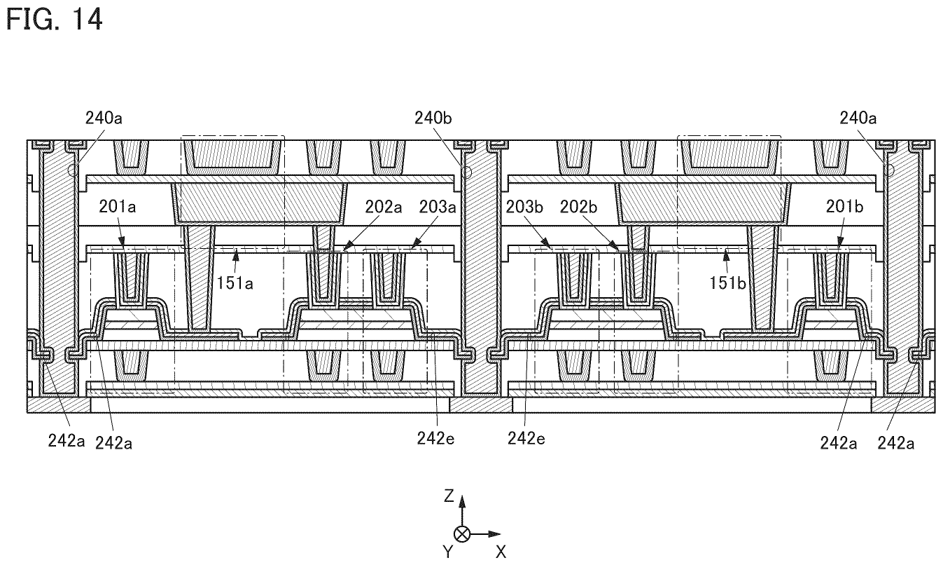

FIG. 14 is a cross-sectional view illustrating an example in which two memory cells are arranged in the X direction. FIG. 14 illustrates a memory cell including a transistor 201a, a transistor 202a, a transistor 203a, and a capacitor 151a respectively as the transistor 201, the transistor 202, the transistor 203, and the capacitor 151, and a memory cell including a transistor 201b, a transistor 202b, a transistor 203b, and a capacitor 151b respectively as the transistor 201, the transistor 202, the transistor 203, and the capacitor 151.

As illustrated in FIG. 14, the conductor 240b can be electrically connected to the conductor 242e included in the transistor 203a and the conductor 242e included in the transistor 203b. Thus, the conductor 240b can be shared by two memory cells adjacent to each other in the X direction, for example. The conductor 240a can be electrically connected to two conductors 242a adjacent to each other in the X direction, for example. Thus, the conductor 240a can also be shared by two memory cells adjacent to each other in the X direction, for example.

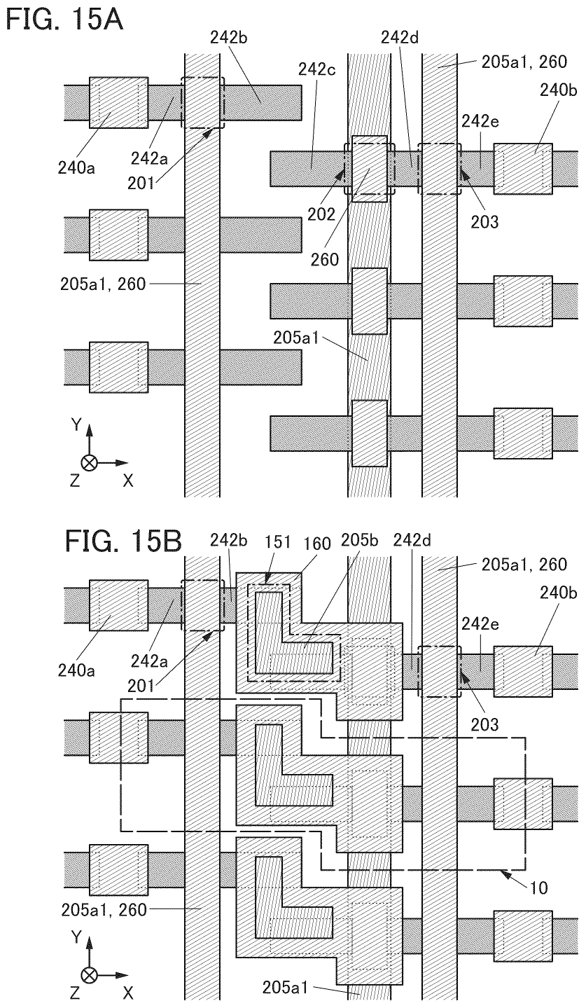

FIG. 15A and FIG. 15B are plan views illustrating examples of the semiconductor device having the structure illustrated in FIG. 9A or the like and illustrate structure examples of the XY plane.

FIG. 15A illustrates the transistor 201, the transistor 202, the transistor 203, the conductor 240a, and the conductor 240b. FIG. 15B illustrates a structure in which the capacitor 151 is added to FIG. 15A. In FIG. 15B, the transistor 201, the transistor 202, the transistor 203, and the capacitor 151 constitute a memory cell 10. Note that the components other than the conductors are omitted in FIG. 15A and FIG. 15B.

As illustrated in FIG. 15B, the conductor 160 including a region functioning as one electrode of the capacitor 151 and the conductor 205b including a region functioning as the other electrode of the capacitor 151 each have a shape more complex than a rectangle, specifically, a shape with a larger number of vertices than a rectangle. Thus, the area occupied by the memory cell 10 can be reduced as compared with the case where the conductor 160 and the conductor 205b are rectangular while the area where the conductor 160 and the conductor 205b overlap with each other is being maintained. Accordingly, the memory cells 10 can be arranged at high density, thereby improving the integration degree of the memory cells 10 and increasing the memory capacity of the semiconductor device. For example, in the case where the conductors illustrated in FIG. 15B are formed with a line-and-space pattern, the area of the memory cell 10 is 80 nm×245 nm=0.0196 μm² when the conductors other than the conductor 240 are designed such that line/space is 20 nm/20 nm and a margin for a portion where two patterns overlap with each other is 10 nm and the conductor 240 is designed with 25 nm×25 nm including a margin for misalignment of 5 nm. The cell density of each of the memory layer 11_1 to the memory layer 11_n illustrated in FIG. 8 is 51.0 cell/μm², for example.

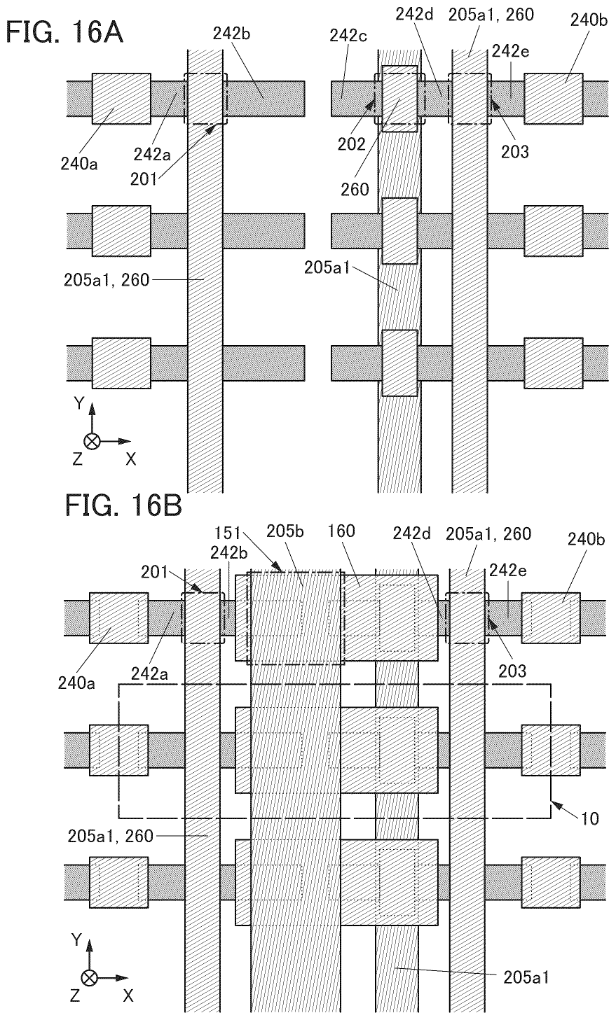

FIG. 16A and FIG. 16B are plan views illustrating examples of the semiconductor device having the structure illustrated in FIG. 9A, which are different from the examples in FIG. 15A and FIG. 15B, and illustrate structure examples of the XY plane.

In the structure illustrated in FIG. 16B, the conductor 160 including the region functioning as one electrode of the capacitor 151 and the conductor 205b including the region functioning as the other electrode of the capacitor 151 are rectangular. Thus, the semiconductor device illustrated in FIG. 16B can be manufactured more easily than the semiconductor device illustrated in FIG. 15B.

At least part of this embodiment can be implemented in appropriate combination with the other embodiments described in this specification.

### Embodiment 3

In this embodiment, a memory device of one embodiment of the present invention will be described with reference to drawings.

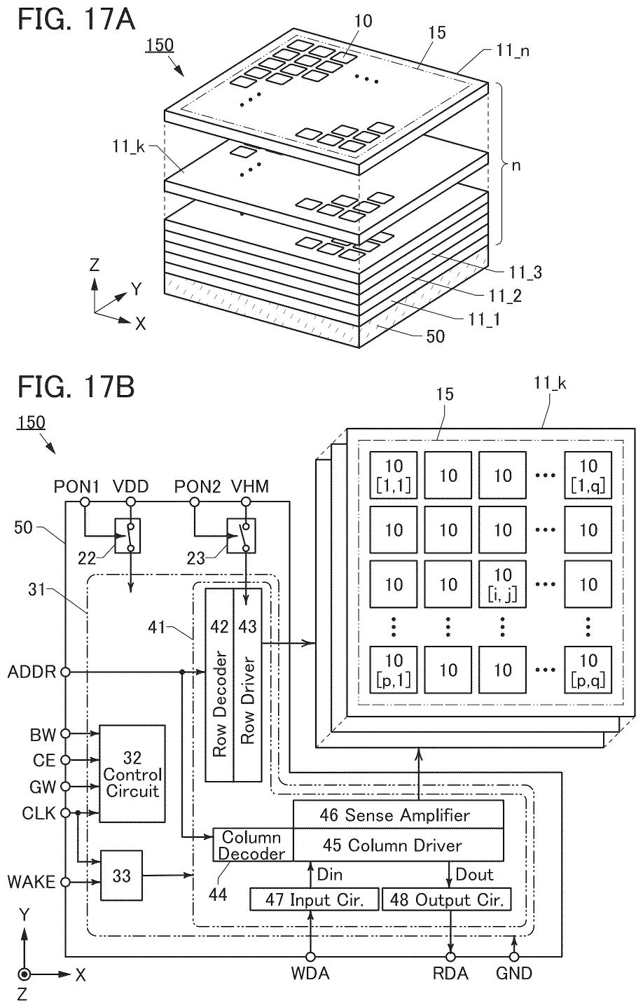

FIG. 17A is a schematic perspective view of a memory device of one embodiment of the present invention. FIG. 17B is a block diagram of the memory device of one embodiment of the present invention.

A memory device 150 illustrated in FIG. 17A and FIG. 17B includes a driver circuit layer 50 and the n memory layers 11. The memory layers 11 each include a memory cell array 15. The memory cell array 15 includes the plurality of memory cells 10.

The n memory layers 11 are provided over the driver circuit layer 50. Provision of the n memory layers 11 over the driver circuit layer 50 can reduce the area occupied by the memory device 150. Furthermore, memory capacity per unit area can be increased.

In this embodiment, the first memory layer 11 is denoted by the memory layer 11_1, the second memory layer 11 is denoted by the memory layer 11_2, and the third memory layer 11 is denoted by a memory layer 11_3. Furthermore, the k-th (k is an integer greater than or equal to 1 and less than or equal to n) memory layer 11 is denoted by a memory layer 11_k, and the n-th memory layer 11 is denoted by the memory layer 11_n. Note that in this embodiment and the like, the simple term “memory layer 11” is sometimes used in the case of describing matters related to all the n memory layers 11 or matters common to the n memory layers 11.

### <Structure Example of Driver Circuit Layer 50>

The driver circuit layer 50 includes a PSW 22 (power switch), a PSW 23, and a peripheral circuit 31. The peripheral circuit 31 includes a peripheral circuit 41, a control circuit 32, and a voltage generation circuit 33.

In the memory device 150, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside.

The signal CLK is a clock signal. The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 32.

The control circuit 32 is a logic circuit having a function of controlling the entire operation of the memory device 150. For example, the control circuit performs a logical operation on the signal CE, the signal GW, and the signal BW to determine an operation mode (e.g., a writing operation or a reading operation) of the memory device 150. Alternatively, the control circuit 32 generates a control signal for the peripheral circuit 41 so that the operation mode is executed.

The voltage generation circuit 33 has a function of generating a negative voltage. The signal WAKE has a function of controlling the input of the signal CLK to the voltage generation circuit 33. For example, when an H-level signal is supplied as the signal WAKE, the signal CLK is input to the voltage generation circuit 33 and the voltage generation circuit 33 generates a negative voltage.

The peripheral circuit 41 is a circuit for writing and reading data to/from the memory cells 10. The peripheral circuit 41 includes a row decoder 42, a column decoder 44, a row driver 43, a column driver 45, an input circuit 47 (Input Cir.), an output circuit 48 (Output Cir.), and a sense amplifier 46.

The row decoder 42 and the column decoder 44 have a function of decoding the signal ADDR. The row decoder 42 is a circuit for specifying a row to be accessed, and the column decoder 44 is a circuit for specifying a column to be accessed. The row driver 43 has a function of selecting a wiring WWL (write word line) or a wiring RWL (read word line) specified by the row decoder 42. The column driver 45 has a function of writing data to the memory cells 10, a function of reading data from the memory cells 10, a function of retaining the read data, and the like. The column driver 45 has a function of selecting a wiring WBL (write bit line) or a wiring RBL (read bit line) specified by the column decoder 44.

The input circuit 47 has a function of retaining the signal WDA. Data retained by the input circuit 47 is output to the column driver 45. Data output from the input circuit 47 is data (Din) to be written to the memory cells 10. Data (Dout) read from the memory cells 10 by the column driver 45 is output to the output circuit 48. The output circuit 48 has a function of retaining Dout. In addition, the output circuit 48 has a function of outputting Dout to the outside of the memory device 150. Data output from the output circuit 48 is the signal RDA.

The PSW 22 has a function of controlling supply of VDD to the peripheral circuit 31. The PSW 23 has a function of controlling supply of VHM to the row driver 43. Here, in the memory device 150, a high power supply voltage is VDD and a low power supply voltage is GND (a ground potential). In addition, VHM is a high power supply voltage used to set a word line at a high level and is higher than VDD. The on/off of the PSW 22 is controlled by the signal PON1, and the on/off of the PSW 23 is controlled by the signal PON2. The number of power domains to which VDD is supplied is one in the peripheral circuit 31 in FIG. 17B but can be more than one. In that case, a power switch is provided for each power domain.

### <Structure Example of Memory Layer 11>

A structure example of the n memory layers 11 is described. The n memory layers 11 each include the memory cell array 15. The memory cell array 15 includes the plurality of memory cells 10. FIG. 17A and FIG. 17B illustrate an example in which the memory cell array 15 includes the plurality of memory cells 10 arranged in a matrix of p rows and q columns (each of p and q is an integer greater than or equal to 2).

Note that the rows and the columns extend in directions orthogonal to each other. In this embodiment, the X direction is referred to as a “row” and the Y direction is referred to as a “column”, but the X direction may be referred to as a “column” and the Y direction may be referred to as a “row”.

In FIG. 17B, the memory cell 10 provided in the first row and the first column is referred to as a memory cell 10[1,1], and the memory cell 10 provided in the p-th row and the q-th column is referred to as a memory cell 10[p,q]. The memory cell 10 provided in the i-th row and the j-th column (i is an integer greater than or equal to 1 and less than or equal to p, and j is an integer greater than or equal to 1 and less than or equal to q) is referred to as a memory cell 10[i,j].

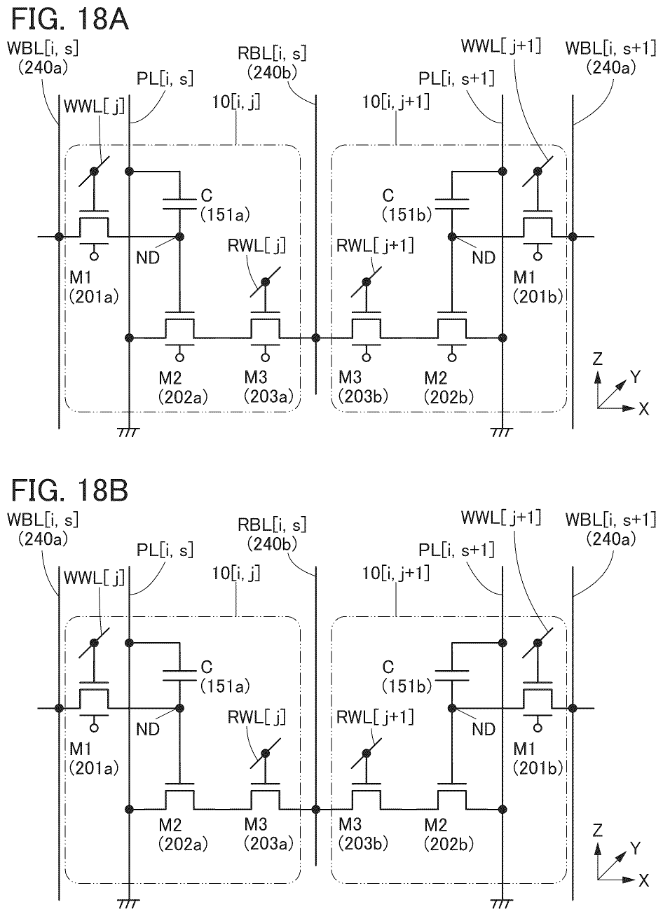

FIG. 18A and FIG. 18B illustrate circuit structure examples of memory cells. Embodiment 1 can be referred to for cross-sectional structure examples of the memory cells 10 corresponding to the circuit structures.

The memory cells 10 each include a transistor M1, a transistor M2, a transistor M3, and a capacitor C. A memory cell composed of three transistors and one capacitor is also referred to as a 3Tr1C memory cell. Thus, the memory cells 10 shown in this embodiment are each a 3Tr1C memory cell.

The transistor M1 corresponds to the transistor 201a or the transistor 201b described in Embodiment 2. The transistor M2 corresponds to the transistor 202 or the transistor 202b described in Embodiment 2. The transistor M3 corresponds to the transistor 203 or the transistor 203b described in Embodiment 2. The capacitor C corresponds to the capacitor 151 described in Embodiment 2. The wiring WBL corresponds to the conductor 240a described in Embodiment 1. The wiring RBL corresponds to the conductor 240b described in Embodiment 2.

In the memory cell 10[i,j], a gate of the transistor M1 is electrically connected to a wiring WWL[j], and one of a source and a drain of the transistor M1 is electrically connected to a wiring WBL[i,s]. Note that FIG. 18A illustrates a structure example in which part of the wiring WWL[j] functions as the gate of the transistor M1. One electrode of the capacitor C is electrically connected to a wiring PL[i,s], and the other electrode is electrically connected to the other of the source and the drain of the transistor M1. Note that FIG. 18A illustrates a structure example in which part of the wiring PL[i,s] functions as the one electrode of the capacitor C, for example. A gate of the transistor M2 is electrically connected to the other electrode of the capacitor C, one of a source and a drain of the transistor M2 is electrically connected to one of a source and a drain of the transistor M3, and the other of the source and the drain of the transistor M2 is electrically connected to the wiring PL[i,s]. A gate of the transistor M3 is electrically connected to a wiring RWL[j], and the other of the source and the drain of the transistor M3 is electrically connected to a wiring RBL[i,s].

In the memory cell 10[i,j], a region where the other electrode of the capacitor C, the other of the source and the drain of the transistor M1, and the gate of the transistor M2 are electrically connected to one another and always have the same potential is referred to as a “node ND”.

In a memory cell 10[i,j+1], the gate of the transistor M1 is electrically connected to a wiring WWL[j+1], and one of the source and the drain of the transistor M1 is electrically connected to a wiring WBL[i,s+1]. Note that FIG. 18A illustrates a structure example in which part of the wiring WWL[j+1] functions as the gate of the transistor M1. One electrode of the capacitor C is electrically connected to a wiring PL[i,s+1], and the other electrode is electrically connected to the other of the source and the drain of the transistor M1. Note that FIG. 18A illustrates a structure example in which part of the wiring PL[i,s+1] functions as the one electrode of the capacitor C, for example. The gate of the transistor M2 is electrically connected to the other electrode of the capacitor C, one of the source and the drain of the transistor M2 is electrically connected to one of the source and the drain of the transistor M3, and the other of the source and the drain of the transistor M2 is electrically connected to the wiring PL[i,s+1]. The gate of the transistor M3 is electrically connected to a wiring RWL[j+1], and the other of the source and the drain of the transistor M3 is electrically connected to the wiring RBL[i,s].

Thus, the wiring RBL[i,s] is electrically connected to the source or the other of the transistor M3 included in the memory cell 10[i,j] and the source or the other of the transistor M3 included in the memory cell 10[i,j+1]. Accordingly, the wiring RBL[i,s] is shared by the memory cell 10[i,j] and the memory cell 10[i,j+1]. Although not illustrated, the wiring WBL[i,s] is shared by a memory cell 10[i,j−1] and the memory cell 10[i,j], and the wiring WBL[i,s+1] is shared by the memory cell 10[i,j+1] and a memory cell 10[i,j+2].

In the memory cell 10[i,j+1], a region where the other electrode of the capacitor C, the other of the source and the drain of the transistor M1, and the gate of the transistor M2 are electrically connected to one another and always have the same potential is referred to as the node ND.

As illustrated in FIG. 18A, a transistor with a back gate may be used as each of the transistor M1, the transistor M2, and the transistor M3. The gate and the back gate are placed such that a channel formation region of a semiconductor is sandwiched between the gate and the back gate. The gate and the back gate are formed using conductors. The back gate can function like the gate. By changing the potential of the back gate, the threshold voltage of the transistor can be changed. The potential of the back gate may be the same as the potential of the gate or may be a ground potential or a given potential.

Note that each of the transistor M1, the transistor M2, and the transistor M3 does not necessarily include a back gate. For example, as illustrated in FIG. 18B, a transistor with a back gate may be used as the transistor M1 and a transistor without a back gate may be used as each of the transistor M2 and the transistor M3.

In addition, the gate and the back gate are formed using conductors and thus also have a function of preventing an electric field generated outside the transistor from affecting the semiconductor in which a channel is formed (particularly, a function of blocking static electricity). That is, a variation in the electrical characteristics of the transistor due to the influence of an external electric field such as static electricity can be inhibited. Moreover, providing the back gate can reduce the amount of change in threshold voltage of the transistor before and after a BT test.

For example, the use of a transistor with a back gate as the transistor M1 can reduce the influence of an external electric field, allowing the off state to be maintained stably. Thus, data written to the node ND can be retained stably. Providing the back gate can stabilize the operation of the memory cells 10 and can improve the reliability of the memory device including the memory cells 10.

Likewise, the use of a transistor with a back gate as the transistor M3 can reduce the influence of an external electric field, allowing the off state to be maintained stably. Thus, leakage current between the wiring RBL and the wiring PL can be reduced, resulting in a reduction in the power consumption of the memory device including the memory cells 10.

As a semiconductor layer in which the channel of each of the transistor M1, the transistor M2, and the transistor M3 is formed, a single crystal semiconductor, a polycrystalline semiconductor, a microcrystalline semiconductor, an amorphous semiconductor, or the like can be used alone or in combination. As a semiconductor material, silicon, germanium, or the like can be used, for example. Alternatively, a compound semiconductor such as silicon germanium, silicon carbide, gallium arsenide, an oxide semiconductor, or a nitride semiconductor may be used.

Note that each of the transistor M1, the transistor M2, and the transistor M3 is preferably a transistor using an oxide semiconductor, which is a kind of metal oxide, in a semiconductor layer in which a channel is formed (also referred to as an “OS transistor”). An oxide semiconductor has a band gap of 2 eV or more and thus has an extremely low off-state current. Thus, the power consumption of the memory cells 10 can be reduced. Accordingly, the power consumption of the memory device 150 including the memory cells 10 can be reduced.

A memory cell including an OS transistor can be referred to as an “OS memory”. The memory device 150 including the memory cell can also be referred to as an “OS memory”.

The OS transistor operates stably even in a high-temperature environment and has a small variation in electrical characteristics. For example, the off-state current hardly increases even in the high-temperature environment. Specifically, the off-state current hardly increases even at an environmental temperature higher than or equal to room temperature and lower than or equal to 200° C. Furthermore, the on-state current is unlikely to decrease even in the high-temperature environment. Thus, the OS memory can operate stably and have high reliability even in the high-temperature environment.

### <Operation Example of Memory Cell 10>

Data writing and reading operation examples of the memory cell 10 will be described. In this embodiment, normally-off n-channel transistors are used as the transistor M1, the transistor M2, and the transistor M3.

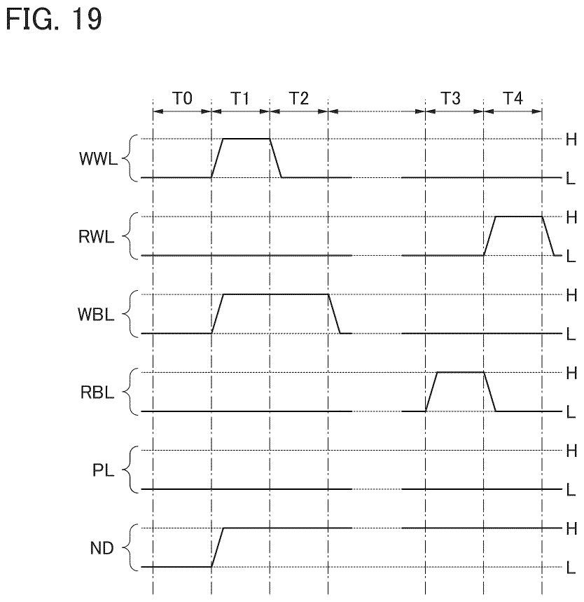

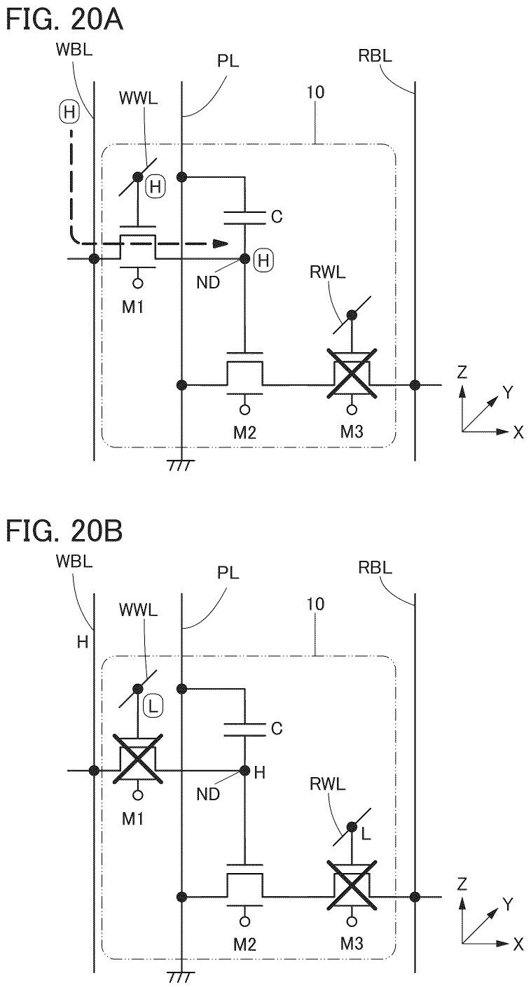

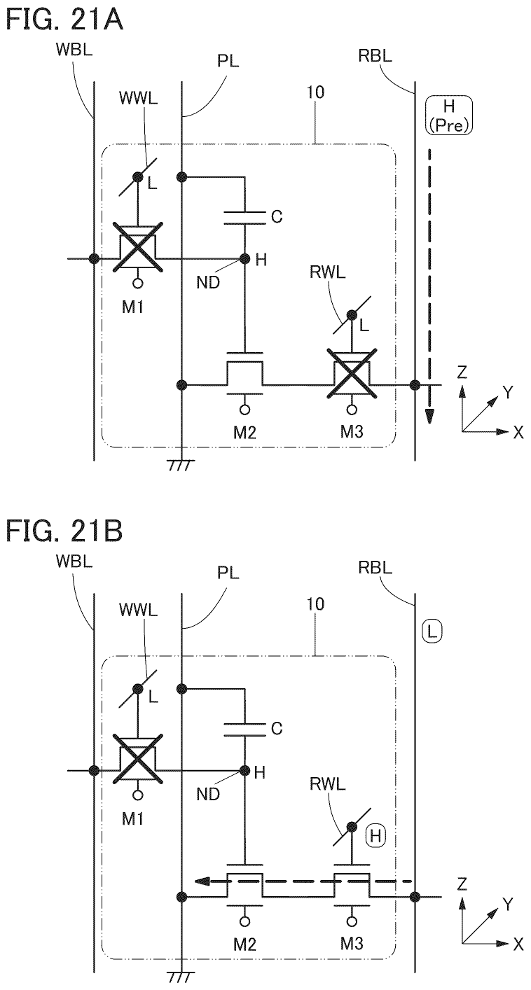

FIG. 19 is a timing chart for describing an operation example of the memory cell 10. FIG. 20A, FIG. 20B, FIG. 21A, and FIG. 21B are circuit diagrams for describing the operation example of the memory cell 10.

In the following drawings and the like, for showing the potentials of a wiring and an electrode, “H” representing a potential H or “L” representing a potential L is sometimes written near the wiring and the electrode. In addition, enclosed “H” or “L” is sometimes written near a wiring or an electrode whose potential changes. Moreover, in the case where a transistor is in an off state, a symbol “x” is sometimes written on the transistor.

When the potential H is supplied to a gate of an n-channel transistor, the transistor is turned on. When the potential L is supplied to a gate of an n-channel transistor, the transistor is turned off. Thus, the potential H is a potential higher than the potential L. The potential H may be a potential equal to the high power supply potential VDD. The potential L is a potential lower than the potential H. The potential L may be a potential equal to the ground potential GND. In this embodiment, the potential L is a potential equal to the ground potential GND.

First, in Period T0, the potentials of the wiring WWL, the wiring RWL, the wiring WBL, the wiring RBL, the wiring PL, and the node ND are the potential L (FIG. 19). In addition, the ground potential GND is supplied to the back gates of the transistor M1, the transistor M2, and the transistor M3.

### [Data Writing Operation]

In Period T1, the potential H is supplied to the wiring WWL and the wiring WBL (FIG. 19 and FIG. 20A). Accordingly, the transistor M1 is turned on and the potential H is written to the node ND as data indicating “1”.

When the potential of the node ND becomes the potential H, the transistor M2 is turned on. Since the potential of the wiring RWL is the potential L, the transistor M3 is in the off state. The transistor M3 in the off state can prevent a short circuit between the wiring RBL and the wiring PL.

### [Retention Operation]

In Period T2, the potential L is supplied to the wiring WWL. Accordingly, the transistor M1 is turned off and the node ND is brought into a floating state. Thus, data (potential H) written to the node ND is retained (FIG. 19 and FIG. 20B). Note that after Period T2, the potential of the wiring WBL becomes the potential L.

As described above, the OS transistor is a transistor having an extremely low off-state current. The use of the OS transistor as the transistor M1 enables data written to the node ND to be retained for a long period. Therefore, it becomes unnecessary to refresh the node ND and the power consumption of the memory cell 10 can be reduced. Thus, the power consumption of the memory device 150 can be reduced.

When the OS transistor is used as one or both of the transistor M2 and the transistor M3, leakage current flowing between the wiring RBL and the wiring PL in the writing operation and the retention operation can be extremely low.

Moreover, the OS transistor has a higher source-drain withstand voltage than a transistor containing silicon in a semiconductor layer where a channel is formed (also referred to as a Si transistor). When the OS transistor is used as the transistor M1, a higher potential can be supplied to the node ND. This increases the range of a potential retained at the node ND. An increase in the range of the potential retained at the node ND makes it easy to retain multilevel data or to retain analog data.

### [Reading Operation]

In Period T3, the potential H is precharged (Pre) to the wiring RBL. That is, the potential of the wiring RBL is set to the potential H and then the wiring RBL is brought into a floating state (FIG. 19 and FIG. 21A).

Next, in Period T4, the potential H is supplied to the wiring RWL, so that the transistor M3 is turned on (FIG. 19 and FIG. 21B). At this time, in the case where the potential of the node ND is the potential H, the transistor M2 is in an on state; thus, electrical continuity is established between the wiring RBL and the wiring PL through the transistor M2 and the transistor M3. When electrical continuity is established between the wiring RBL and the wiring PL, the potential of the wiring RBL, which is in a floating state, changes from the potential H to the potential L.

Note that the transistor M2 is in an off state in the case where the potential L is written to the node ND as data indicating “0”. Thus, electrical continuity is not established between the wiring RBL and the wiring PL even when the transistor M3 is turned on, and the potential of the wiring RBL remains the potential H.

By detecting a change in the potential of the wiring RBL at the time of supplying the potential H to the wiring RWL in this manner, data written to the memory cell 10 can be read.

The memory cell 10 using the OS transistor employs a method in which charge is written to the node ND through the OS transistor; hence, a high voltage, which is required for a conventional flash memory, is unnecessary and a high-speed writing operation is possible. Furthermore, unlike in a flash memory, the number of times of data writing and reading in the memory cell 10 using the OS transistor is substantially unlimited because charge injection and extraction into/from a floating gate or a charge-trap layer are not performed. Unlike in a flash memory, unstableness due to an increase of electron trap centers is not observed in the memory cell 10 using the OS transistor even when a rewriting operation is repeated. The memory cell 10 using the OS transistor is less likely to degrade than a conventional flash memory and can have high reliability.

Unlike a magnetic memory, a resistive random access memory, or the like, the memory cell 10 using the OS transistor has no change in the structure at the atomic level. Thus, the memory cell 10 using the OS transistor has higher rewrite endurance than a magnetic memory and a resistive random access memory.

### <Structure Example of Sense Amplifier 46>

Next, a structure example of the sense amplifier 46 will be described. Specifically, a structure example of a write read circuit that includes the sense amplifier 46 and performs writing or reading of a data signal will be described.

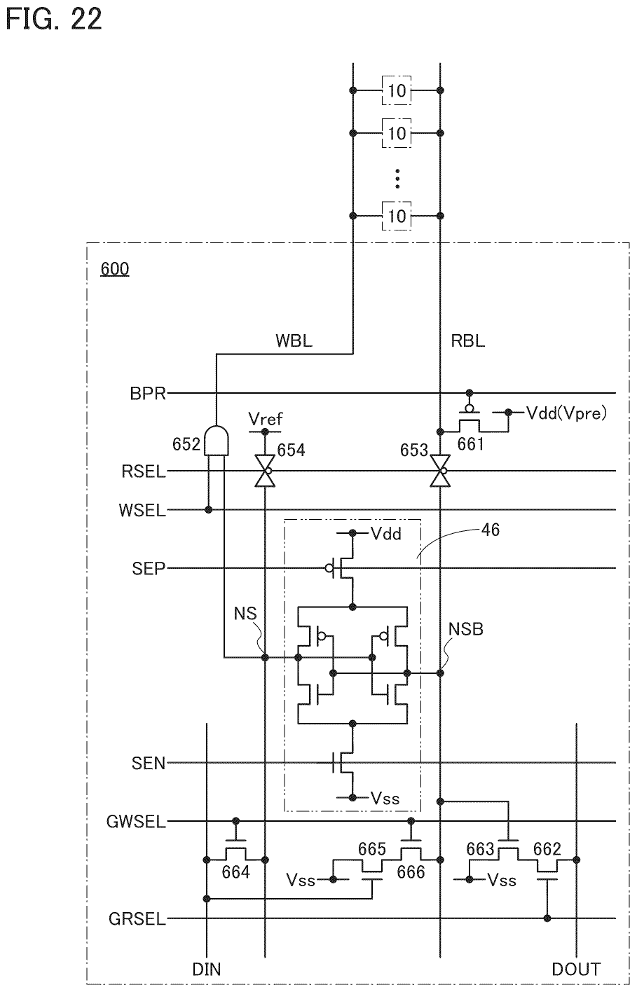

FIG. 22 is a circuit diagram illustrating a structure example of a circuit 600 that includes the sense amplifier 46 and performs writing or reading of a data signal. The circuit 600 is provided for every wiring WBL and every wiring RBL.

The circuit 600 includes a transistor 661 to a transistor 666, the sense amplifier 46, an AND circuit 652, an analog switch 653, and an analog switch 654.

The circuit 600 operates in accordance with a signal SEN, a signal SEP, a signal BPR, a signal RSEL, a signal WSEL, a signal GRSEL, and a signal GWSEL.

Data DIN input to the circuit 600 is written to the memory cell 10 through the wiring WBL electrically connected to a node NS through the AND circuit 652. Data DOUT written to the memory cell 10 is transmitted to the wiring RBL electrically connected to a node NSB through the analog switch 653 and output from the circuit 600 as the data DOUT.

Note that the data DIN and the data DOUT are internal signals and respectively correspond to the signal WDA and the signal RDA.

The transistor 661 is included in a precharge circuit. The wiring RBL is precharged to a precharge potential Vpre by the transistor 661. Note that in this embodiment, the case where a potential Vdd (high level) is used as the precharge potential Vpre will be described (denoted by Vdd (Vpre) in FIG. 22). The signal BPR is a precharge signal, and the conduction state of the transistor 661 is controlled by the signal BPR.

In a reading operation, the sense amplifier 46 determines whether data input to the wiring RBL is at a high level or a low level. In a writing operation, the sense amplifier 46 functions as a latch circuit that temporarily retains the data DIN input to the circuit 600.

The sense amplifier 46 illustrated in FIG. 22 is a latch sense amplifier. The sense amplifier 46 includes two inverter circuits, and an input node of one of the inverter circuits is connected to an output node of the other of the inverter circuits. When the input node of the one of the inverter circuits is the node NS and the output node is the node NSB, complementary data is retained at the node NS and the node NSB.

The signal SEN and the signal SEP are each a sense amplifier enable signal for activating the sense amplifier 46, and a reference potential Vref is a read judge potential. The sense amplifier 46 determines whether the potential of the node NSB at the time of the activation is at a high level or a low level on the basis of the reference potential Vref.

The AND circuit 652 controls electrical continuity between the node NS and the wiring WBL. The analog switch 653 controls electrical continuity between the node NSB and the wiring RBL. The analog switch 654 controls electrical continuity between the node NS and a wiring supplying the reference potential Vref.

In data reading, the potential of the wiring RBL is transmitted to the node NSB by the analog switch 653. When the potential of the wiring RBL is lower than the reference potential Vref, the sense amplifier 46 determines that the wiring RBL is at a low level. The sense amplifier 46 determines that the wiring RBL is at a high level when the potential of the wiring RBL does not become lower than the reference potential Vref.

The signal WSEL is a write selection signal and controls the AND circuit 652. The signal RSEL is a read selection signal and controls the analog switch 653 and the analog switch 654.

The transistor 662 and the transistor 663 are included in an output MUX (multiplexer) circuit. The signal GRSEL is a global read selection signal and controls the output MUX circuit. The output MUX circuit has a function of selecting the wiring RBL from which data is to be read.

The output MUX circuit has a function of outputting the data DOUT read from the sense amplifier 46.

The transistor 664 to the transistor 666 are included in a write driver circuit. The signal GWSEL is a global write selection signal and controls the write driver circuit. The write driver circuit has a function of writing the data DIN to the sense amplifier 46.

The write driver circuit has a function of selecting a column to which the data DIN is to be written. The write driver circuit writes data in byte units, half-word units, or word units in response to the signal GWSEL.

In a gain-cell memory cell, at least two transistors are required for one memory cell, which makes it difficult to increase the number of memory cells that can be placed per unit area. However, when an OS transistor is used as a transistor included in the memory cell 10, the plurality of memory cell arrays 15 can be stacked. That is, the amount of data that can be stored per unit area can be increased. A gain-cell memory cell can operate as a memory by amplifying accumulated charge by the closest transistor even when the capacitance of accumulated charge is small. When an OS transistor with an extremely low off-state current is used as a transistor included in the memory cell 10, the capacitance of the capacitor can be made small. Furthermore, one or both of the gate capacitance of a transistor and the parasitic capacitance of a wiring can be used as the capacitor, so that the capacitor can be omitted. That is, the area of the memory cell 10 can be made small.

This embodiment can be combined with the other embodiments as appropriate.

### Embodiment 4

In this embodiment, an example of a chip on which the memory device of one embodiment of the present invention is mounted will be described with reference to drawings.

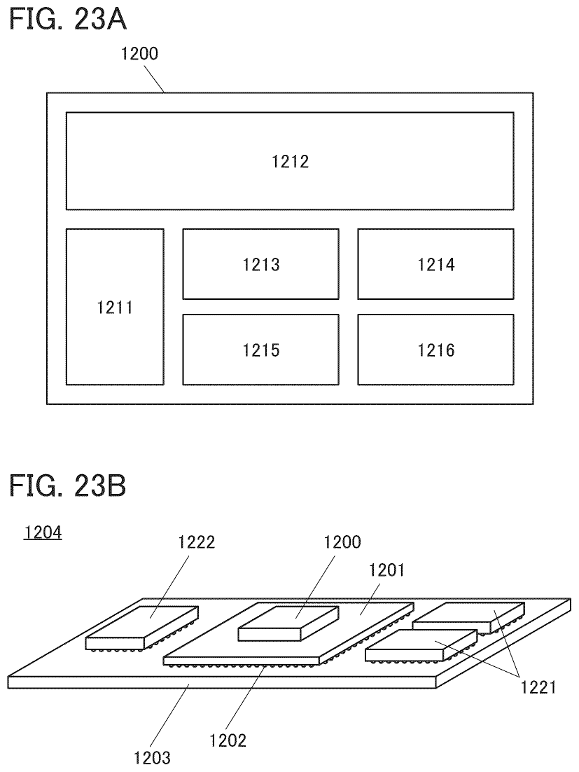

A plurality of circuits (systems) are mounted on a chip 1200 illustrated in FIG. 23A and FIG. 23B. A technique for integrating a plurality of circuits (systems) into one chip is referred to as system on chip (SoC) in some cases.

As illustrated in FIG. 23A, the chip 1200 includes a CPU 1211, a GPU 1212, one or more analog arithmetic units 1213, one or more memory controllers 1214, one or more interfaces 1215, one or more network circuits 1216, and the like.

The chip 1200 is provided with a bump (not illustrated) and is connected to a first surface of a package substrate 1201 as illustrated in FIG. 23B. In addition, a plurality of bumps 1202 are provided on a rear side of the first surface of the package substrate 1201, and the package substrate 1201 is connected to a motherboard 1203.

Memory devices such as DRAMs 1221 and a flash memory 1222 may be provided over the motherboard 1203. For example, the NOSRAM described in the above embodiment can be used as the DRAM 1221. This can make the DRAM 1221 have low power consumption, operate at high speed, and have a large capacity.

The CPU 1211 preferably includes a plurality of CPU cores. In addition, the GPU 1212 preferably includes a plurality of GPU cores. Furthermore, the CPU 1211 and the GPU 1212 may each include a memory for temporarily storing data. Alternatively, a common memory for the CPU 1211 and the GPU 1212 may be provided in the chip 1200. The NOSRAM described above can be used as the memory. Moreover, the GPU 1212 is suitable for parallel computation of a large amount of data and thus can be used for image processing or a product-sum operation. When an image processing circuit or a product-sum operation circuit using an OS transistor is provided in the GPU 1212, image processing or a product-sum operation can be performed with low power consumption.

In addition, since the CPU 1211 and the GPU 1212 are provided on the same chip, a wiring between the CPU 1211 and the GPU 1212 can be shortened, and data transfer from the CPU 1211 to the GPU 1212, data transfer between memories included in the CPU 1211 and the GPU 1212, and transfer of arithmetic operation results from the GPU 1212 to the CPU 1211 after the arithmetic operation in the GPU 1212 can be performed at a high speed.

The analog arithmetic unit 1213 includes one or both of an A/D (analog/digital) converter circuit and a D/A (digital/analog) converter circuit. Furthermore, the product-sum operation circuit may be provided in the analog arithmetic unit 1213.

The memory controller 1214 includes a circuit functioning as a controller of the DRAM 1221 and a circuit functioning as an interface of the flash memory 1222.

The interface 1215 includes an interface circuit for an external connection device such as a display device, a speaker, a microphone, a camera, or a controller. Examples of the controller include a mouse, a keyboard, and a game controller. As such an interface, a USB (Universal Serial Bus), an HDMI (registered trademark) (High-Definition Multimedia Interface), or the like can be used.

The network circuit 1216 includes a network circuit such as a LAN (Local Area Network). The network circuit 1216 may further include a circuit for network security.

The circuits (systems) can be formed in the chip 1200 through the same manufacturing process. Therefore, even when the number of circuits needed for the chip 1200 increases, there is no need to increase the number of steps in the manufacturing process; thus, the chip 1200 can be manufactured at low cost.

The motherboard 1203 provided with the package substrate 1201 on which the chip 1200 including the GPU 1212 is mounted, the DRAMs 1221, and the flash memory 1222 can be referred to as a GPU module 1204.

The GPU module 1204 includes the chip 1200 using SoC technology, and thus can have a small size. In addition, the GPU module 1204 is excellent in image processing, and thus is suitably used in a portable electronic device such as a smartphone, a tablet terminal, a laptop PC, or a portable (mobile) game machine. Furthermore, the product-sum operation circuit using the GPU 1212 can perform a method such as a deep neural network (DNN), a convolutional neural network (CNN), a recurrent neural network (RNN), an autoencoder, a deep Boltzmann machine (DBM), or a deep belief network (DBN); hence, the chip 1200 can be used as an AI chip or the GPU module 1204 can be used as an AI system module.

This embodiment can be combined with the other embodiments as appropriate.

### Embodiment 5

In this embodiment, examples of an electronic component incorporating the memory device of one embodiment of the present invention will be described.

### [Electronic Component]

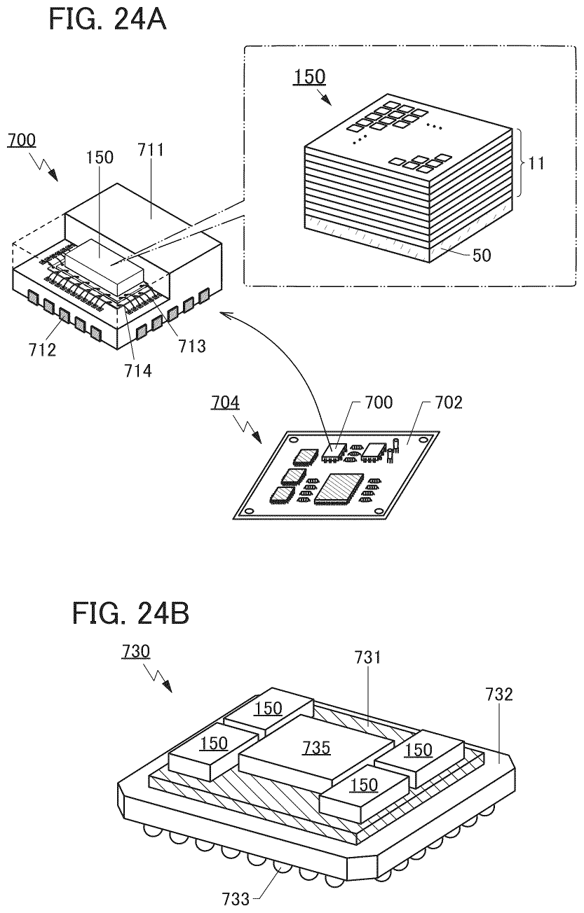

FIG. 24A is a perspective view of an electronic component 700 and a substrate (a circuit board 704) on which the electronic component 700 is mounted. The electronic component 700 illustrated in FIG. 24A includes the memory device 150 that is the memory device of one embodiment of the present invention in a mold 711. FIG. 24A omits part of the electronic component to illustrate the inside of the electronic component 700. The electronic component 700 includes a land 712 outside the mold 711. The land 712 is electrically connected to an electrode pad 713, and the electrode pad 713 is electrically connected to the memory device 150 through a wire 714. The electronic component 700 is mounted on a printed circuit board 702, for example. A plurality of such electronic components are combined and electrically connected to each other on the printed circuit board 702, so that the circuit board 704 is completed.

As described in the above embodiment, the memory device 150 includes the driver circuit layer 50 and the memory layers 11 (each including the memory cell array 15).

FIG. 24B is a perspective view of an electronic component 730. The electronic component 730 is an example of a SiP (System in package) or an MCM (Multi Chip Module). In the electronic component 730, an interposer 731 is provided over a package substrate 732 (printed circuit board), and a semiconductor device 735 and a plurality of the memory devices 150 are provided over the interposer 731.

The electronic component 730 using the memory devices 150 as high bandwidth memory (HBM) is illustrated as an example. An integrated circuit (a semiconductor device) such as a CPU, a GPU, or an FPGA can be used as the semiconductor device 735.

As the package substrate 732, for example, a ceramic substrate, a plastic substrate, or a glass epoxy substrate can be used. As the interposer 731, for example, a silicon interposer or a resin interposer can be used.

The interposer 731 includes a plurality of wirings and has a function of electrically connecting a plurality of integrated circuits with different terminal pitches. The plurality of wirings are provided in a single layer or multiple layers. The interposer 731 has a function of electrically connecting an integrated circuit provided over the interposer 731 to an electrode provided over the package substrate 732. Accordingly, the interposer is sometimes referred to as a “redistribution substrate” or an “intermediate substrate”. A through electrode may be provided in the interposer 731 to be used for electrically connecting the integrated circuit and the package substrate 732. In a silicon interposer, a TSV (Through Silicon Via) can also be used as the through electrode.

A silicon interposer is preferably used as the interposer 731. The silicon interposer can be manufactured at lower cost than an integrated circuit because it is not necessary to provide an Moreover, since wirings of a silicon interposer can be formed through a active element. semiconductor process, formation of minute wirings, which is difficult for a resin interposer, is easily achieved.

In order to achieve a wide memory bandwidth, many wirings need to be connected to an HBM. Therefore, formation of minute and high-density wirings is required for an interposer on which an HBM is mounted. For this reason, a silicon interposer is preferably used as the interposer on which an HBM is mounted.

In a SiP, an MCM, and the like using a silicon interposer, a decrease in reliability due to a difference in expansion coefficient between an integrated circuit and the interposer is less likely to occur. Furthermore, a surface of a silicon interposer has high planarity, so that a poor connection between the silicon interposer and an integrated circuit provided over the silicon interposer is less likely to occur. It is particularly preferable to use a silicon interposer for a 2.5D package (2.5-dimensional mounting) in which a plurality of integrated circuits are arranged side by side over the interposer.

A heat sink (radiator plate) may be provided to overlap with the electronic component 730. In the case of providing a heat sink, the heights of integrated circuits provided over the interposer 731 are preferably the same. In the electronic component 730 described in this embodiment, the heights of the memory devices 150 and the semiconductor device 735 are preferably the same, for example.

An electrode 733 may be provided on the bottom portion of the package substrate 732 to mount the electronic component 730 on another substrate. FIG. 24B illustrates an example in which the electrode 733 is formed of a solder ball. Solder balls are provided in a matrix on the bottom portion of the package substrate 732, whereby BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by various mounting methods not limited to BGA and PGA. Examples of a mounting method include SPGA (Staggered Pin Grid Array), LGA (Land Grid Array), QFP (Quad Flat Package), QFJ (Quad Flat J-leaded package), and QFN (Quad Flat Non-leaded package).

This embodiment can be combined with the other embodiments as appropriate.

### Embodiment 6

In this embodiment, application examples of the memory device of one embodiment of the present invention will be described.

The memory device of one embodiment of the present invention can be used as memory devices of a variety of electronic devices (e.g., information terminals, computers, smartphones, e-book readers, digital still cameras, video cameras, video recording/reproducing devices, navigation systems, and game machines). The memory device can also be used for image sensors, IoT (Internet of Things), healthcare-related devices, and the like. Note that here, the computers refer not only to tablet computers, laptop computers, and desktop computers, but also to large computers such as server systems.

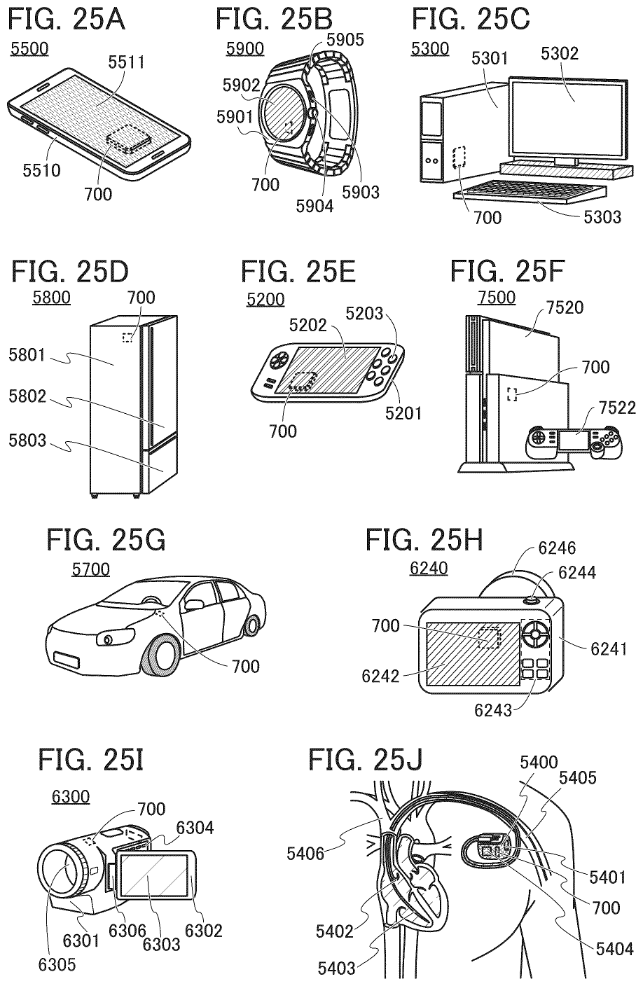

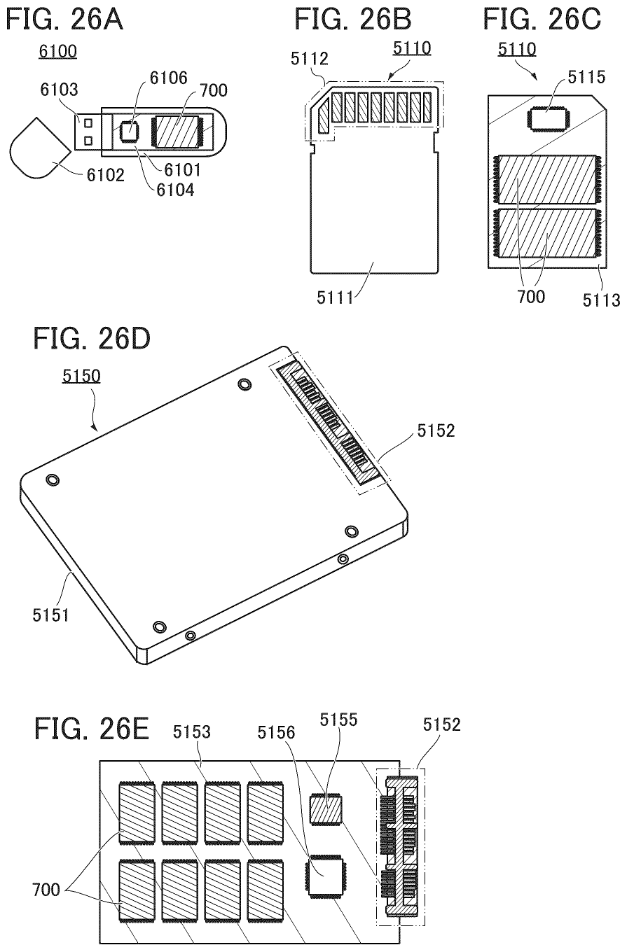

Examples of an electronic device including the memory device of one embodiment of the present invention will be described. Note that FIG. 25A to FIG. 25J and FIG. 26A to FIG. 26E each illustrate a state where the electronic component 700 or the electronic component 730 that includes the memory device described in the above embodiments is included in an electronic device.

### [Mobile Phone]

An information terminal 5500 illustrated in FIG. 25A is a mobile phone (smartphone), which is a type of information terminal. The information terminal 5500 includes a housing 5510 and a display portion 5511, and as input interfaces, a touch panel is provided in the display portion 5511 and a button is provided in the housing 5510.

By using the memory device of one embodiment of the present invention, the information terminal 5500 can retain a temporary file generated at the time of executing an application (e.g., a web browser's cache).

### [Wearable Terminal]

FIG. 25B illustrates an information terminal 5900 as an example of a wearable terminal. The information terminal 5900 includes a housing 5901, a display portion 5902, an operation switch 5903, an operation switch 5904, a band 5905, and the like.

Like the information terminal 5500 described above, the wearable terminal can retain a temporary file generated at the time of executing an application by using the memory device of one embodiment of the present invention.

### [Information Terminal]

FIG. 25C illustrates a desktop information terminal 5300. The desktop information terminal 5300 includes a main body 5301 of the information terminal, a display portion 5302, and a keyboard 5303.

Like the information terminal 5500 described above, the desktop information terminal 5300 can retain a temporary file generated at the time of executing an application by using the memory device of one embodiment of the present invention.

FIG. 25A to FIG. 25C illustrate the smartphone, the wearable terminal, and the desktop information terminal as electronic devices, and examples of other information terminals include a PDA (Personal Digital Assistant), a laptop information terminal, and a workstation.

### [Household Appliance]

FIG. 25D illustrates an electric refrigerator-freezer 5800 as an example of a household appliance. The electric refrigerator-freezer 5800 includes a housing 5801, a refrigerator door 5802, a freezer door 5803, and the like. For example, the electric refrigerator-freezer 5800 is an electric refrigerator-freezer that is compatible with IoT (Internet of Things).

The memory device of one embodiment of the present invention can be used in the electric refrigerator-freezer 5800. The electric refrigerator-freezer 5800 can transmit and receive information on food stored in the electric refrigerator-freezer 5800 and food expiration dates, for example, to and from an information terminal via the Internet. In the electric refrigerator-freezer 5800, the memory device of one embodiment of the present invention can retain a temporary file generated at the time of transmitting the information.

FIG. 25D illustrates the electric refrigerator-freezer as a household appliance, and examples of other household appliances include a vacuum cleaner, a microwave oven, an electric oven, a rice cooker, a water heater, an IH cooker, a water server, a heating-cooling combination appliance such as an air conditioner, a washing machine, a drying machine, and an audiovisual appliance.

### [Game Machine]

FIG. 25E illustrates a portable game machine 5200 as an example of a game machine. The portable game machine 5200 includes a housing 5201, a display portion 5202, a button 5203, and the like.

FIG. 25F illustrates a stationary game machine 7500 as an example of a game machine. The stationary game machine 7500 can be especially referred to as a home-use stationary game machine. The stationary game machine 7500 includes a main body 7520 and a controller 7522. Note that the controller 7522 can be connected to the main body 7520 with or without a wire. Although not illustrated in FIG. 25F, the controller 7522 can include a display portion that displays a game image, and an input interface besides the button, such as a touch panel, a stick, a rotating knob, and a sliding knob. The shape of the controller 7522 is not limited to that illustrated in FIG. 25F, and the shape of the controller 7522 may be changed in various ways in accordance with the genres of games. For example, for a shooting game such as an FPS (First Person Shooter) game, a gun-shaped controller having a trigger button can be used. For another example, for a music game, a controller having a shape of a musical instrument, audio equipment, or the like can be used. Furthermore, the stationary game machine may include one or more of a camera, a depth sensor, and a microphone so that the game player can play a game using a gesture or a voice instead of a controller.

Videos displayed on the game machine can be output with a display device such as a television device, a personal computer display, a game display, or a head-mounted display.

By using the memory device of one embodiment of the present invention in the portable game machine 5200 or the stationary game machine 7500, power consumption can be reduced. Moreover, heat generation from a circuit can be reduced owing to low power consumption; thus, the influence of heat generation on the circuit itself, a peripheral circuit, and a module can be reduced.

Moreover, by using the memory device of one embodiment of the present invention, the portable game machine 5200 or the stationary game machine 7500 can retain a temporary file or the like necessary for an arithmetic operation that occurs during game play.

FIG. 25E and FIG. 25F illustrate the portable game machine and the home-use stationary game machine as examples of game machines, and examples of other game machines include an arcade game machine installed in an entertainment facility (e.g., a game center and an amusement park) and a throwing machine for batting practice, installed in sports facilities.

### [Moving Vehicle]

The memory device of one embodiment of the present invention can be used in an automobile, which is a moving vehicle, and the periphery of a driver's seat in the automobile.

FIG. 25G illustrates an automobile 5700 as an example of a moving vehicle.

An instrument panel that provides various kinds of information by displaying a speedometer, a tachometer, a mileage, a fuel meter, a gearshift state, air-conditioning settings, and the like is provided around the driver's seat in the automobile 5700. In addition, a memory device showing the above information may be provided around the driver's seat.

In particular, the display device can compensate for the view obstructed by a pillar, blind areas for the driver's seat, and the like by displaying a video from an imaging device (not illustrated) provided for the automobile 5700, which can improve safety. That is, displaying an image taken by the imaging device provided on the exterior of the automobile 5700 can compensate for blind areas and improve safety.

The memory device of one embodiment of the present invention can temporarily retain information; thus, the memory device can be used to retain temporary information necessary in a system conducting automatic driving, navigation, risk prediction, or the like for the automobile 5700, for example. Moreover, the memory device of one embodiment of the present invention may be configured to retain a video of a driving recorder provided in the automobile 5700.

Although the automobile is described above as an example of a moving vehicle, the moving vehicle is not limited to the automobile. Examples of the moving vehicle include a train, a monorail train, a ship, and a flying object (a helicopter, an unmanned aircraft (drone), an airplane, or a rocket).

### [Camera]

The memory device of one embodiment of the present invention can be used in a camera.

FIG. 25H illustrates a digital camera 6240 as an example of an imaging device. The digital camera 6240 includes a housing 6241, a display portion 6242, operation switches 6243, a shutter button 6244, and the like, and a detachable lens 6246 is attached to the digital camera 6240. Note that the digital camera 6240 is configured here such that the lens 6246 is detachable from the housing 6241 for replacement; alternatively, the lens 6246 may be integrated with the housing 6241. Moreover, the digital camera 6240 may be configured to be additionally equipped with a stroboscope, a viewfinder, or the like.

By using the memory device of one embodiment of the present invention, the digital camera 6240 can have low power consumption. Moreover, heat generation from a circuit can be reduced owing to low power consumption; thus, the influence of heat generation on the circuit itself, a peripheral circuit, and a module can be reduced.

### [Video Camera]

The memory device of one embodiment of the present invention can be used in a video camera.

FIG. 25I illustrates a video camera 6300 as an example of an imaging device. The video camera 6300 includes a first housing 6301, a second housing 6302, a display portion 6303, an operation switch 6304, a lens 6305, a joint 6306, and the like. The operation switch 6304 and the lens 6305 are provided in the first housing 6301, and the display portion 6303 is provided in the second housing 6302. The first housing 6301 and the second housing 6302 are connected to each other with the joint 6306, and the angle between the first housing 6301 and the second housing 6302 can be changed with the joint 6306. Videos displayed on the display portion 6303 may be switched in accordance with the angle at the joint 6306 between the first housing 6301 and the second housing 6302.

When a video taken by the video camera 6300 is recorded, the video needs to be encoded in accordance with a data recording format. With the use of the memory device of one embodiment of the present invention, the video camera 6300 can retain a temporary file generated at the time of encoding.

### [ICD]

The memory device of one embodiment of the present invention can be used in an implantable cardioverter-defibrillator (ICD).

FIG. 25J is a schematic cross-sectional view illustrating an example of an ICD. An ICD main unit 5400 includes at least a battery 5401, the electronic component 700, a regulator, a control circuit, an antenna 5404, a wire 5402 reaching a right atrium, and a wire 5403 reaching a right ventricle.

The ICD main unit 5400 is implanted in the body by surgery, and the two wires pass through a subclavian vein 5405 and a superior vena cava 5406 of the human body, with the end of one of the wires placed in the right ventricle and the end of the other wire placed in the right atrium.

The ICD main unit 5400 functions as a pacemaker and paces the heart when the heart rate is not within a predetermined range. When the heart rate is not recovered by pacing (e.g., when ventricular tachycardia or ventricular fibrillation occurs), treatment with an electrical shock is performed.

The ICD main unit 5400 needs to monitor the heart rate all the time in order to perform pacing and deliver electrical shocks as appropriate. For that reason, the ICD main unit 5400 includes a sensor for measuring the heart rate. In the ICD main unit 5400, data on the heart rate obtained by the sensor, the number of times the treatment with pacing is performed, and the time taken for the treatment, for example, can be stored in the electronic component 700.

The antenna 5404 can receive electric power, and the battery 5401 is charged with the electric power. When the ICD main unit 5400 includes a plurality of batteries, the safety can be improved. Specifically, even when some of the batteries in the ICD main unit 5400 are dead, the other batteries can work properly; hence, the batteries also function as an auxiliary power source.

In addition to the antenna 5404 that can receive electric power, an antenna that can transmit a physiological signal may be included to construct, for example, a system that monitors cardiac activity by checking physiological signals such as a pulse, a respiratory rate, a heart rate, and body temperature with an external monitoring device.

### [Expansion Device for PC]

The memory device of one embodiment of the present invention can be used in a computer such as a PC (Personal Computer) and an expansion device for an information terminal.

FIG. 26A illustrates, as an example of the expansion device, a portable expansion device 6100 that is externally attached to a PC and includes a chip capable of storing information. The expansion device 6100 can store information using the chip when connected to a PC with a USB (Universal Serial Bus), for example. Note that FIG. 26A illustrates the portable expansion device 6100; however, the expansion device of one embodiment of the present invention is not limited thereto and may be a relatively large expansion device including a cooling fan, for example.

The expansion device 6100 includes a housing 6101, a cap 6102, a USB connector 6103, and a substrate 6104. The substrate 6104 is held in the housing 6101. The substrate 6104 is provided with a circuit for driving the memory device of one embodiment of the present invention, for example. The substrate 6104 is provided with the electronic component 700 and a controller chip 6106, for example. The USB connector 6103 functions as an interface for connection to an external device.

### [SD Card]

The memory device of one embodiment of the present invention can be used in an SD card that can be attached to an electronic device such as an information terminal or a digital camera.

FIG. 26B is a schematic external view of an SD card, and FIG. 26C is a schematic view of the internal structure of the SD card. An SD card 5110 includes a housing 5111, a connector 5112, and a substrate 5113. The connector 5112 functions as an interface for connection to an external device. The substrate 5113 is held in the housing 5111. The substrate 5113 is provided with a memory device and a circuit for driving the memory device. For example, the substrate 5113 is provided with the electronic component 700 and a controller chip 5115. Note that the circuit structures of the electronic component 700 and the controller chip 5115 are not limited to those described above, and the circuit structures may be changed as appropriate depending on circumstances. For example, a write circuit, a row driver, a read circuit, or the like provided in an electronic component may be incorporated into the controller chip 5115 instead of the electronic component 700.

When the electronic component 700 is also provided on the back surface side of the substrate 5113, the capacity of the SD card 5110 can be increased. In addition, a wireless chip with a wireless communication function may be provided on the substrate 5113. This enables wireless communication between an external device and the SD card 5110, making it possible to write and read data to/from the electronic component 700.

### [SSD]

The memory device of one embodiment of the present invention can be used in an SSD (Solid State Drive) that can be attached to an electronic device such as an information terminal.

FIG. 26D is a schematic external view of an SSD, and FIG. 26E is a schematic view of the internal structure of the SSD. An SSD 5150 includes a housing 5151, a connector 5152, and a substrate 5153. The connector 5152 functions as an interface for connection to an external device. The substrate 5153 is held in the housing 5151. The substrate 5153 is provided with a memory device and a circuit for driving the memory device. For example, the substrate 5153 is provided with the electronic component 700, a memory chip 5155, and a controller chip 5156. When the electronic component 700 is also provided on the back surface side of the substrate 5153, the capacity of the SSD 5150 can be increased. A work memory is incorporated into the memory chip 5155. For example, a DRAM chip is used as the memory chip 5155. A processor, an ECC (Error-Correcting Code) circuit, and the like are incorporated into the controller chip 5156. Note that the circuit structures of the electronic component 700, the memory chip 5155, and the controller chip 5115 are not limited to those described above, and the circuit structures may be changed as appropriate depending on circumstances. For example, a memory functioning as a work memory may also be provided in the controller chip 5156.

### [Computer]

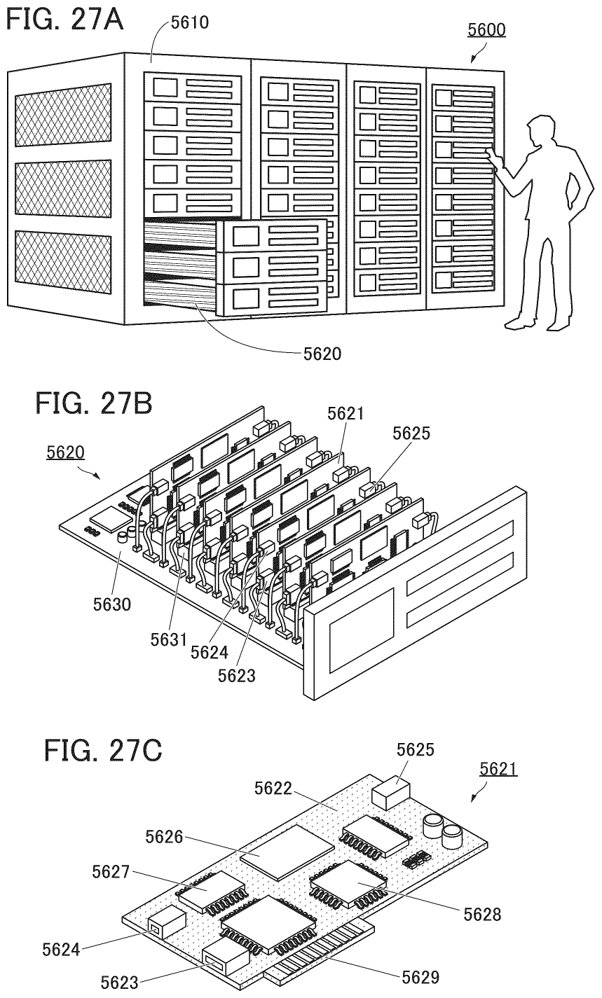

A computer 5600 illustrated in FIG. 27A is an example of a large computer. In the computer 5600, a plurality of rack mount computers 5620 are stored in a rack 5610.

The computer 5620 can have a structure in a perspective view illustrated in FIG. 27B, for example. In FIG. 27B, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 27C is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. FIG. 27C also illustrates semiconductor devices other than the semiconductor device 5626, the semiconductor device 5627, and the semiconductor device 5628; the following description of the semiconductor device 5626, the semiconductor device 5627, and the semiconductor device 5628 is referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve, for example, as an interface for performing power supply, signal input, or the like to the PC card 5621. For another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA (Field Programmable Gate Array), a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. As the semiconductor device 5628, the electronic component 700 can be used, for example.

The computer 5600 can also function as a parallel computer. When the computer 5600 is used as a parallel computer, large-scale computation necessary for artificial intelligence learning and inference can be performed, for example.

The memory device of one embodiment of the present invention is used in a variety of electronic devices and the like described above, whereby a reduction in size and a reduction in power consumption of the electronic devices can be achieved. In addition, since the memory device of one embodiment of the present invention has low power consumption, heat generation from a circuit can be reduced. Accordingly, it is possible to reduce adverse effects of the heat generation on the circuit itself, a peripheral circuit, and a module. Furthermore, the use of the memory device of one embodiment of the present invention can achieve an electronic device that operates stably even in a high-temperature environment. Thus, the reliability of the electronic device can be improved.

This embodiment can be combined with the other embodiments as appropriate.

### Embodiment 7

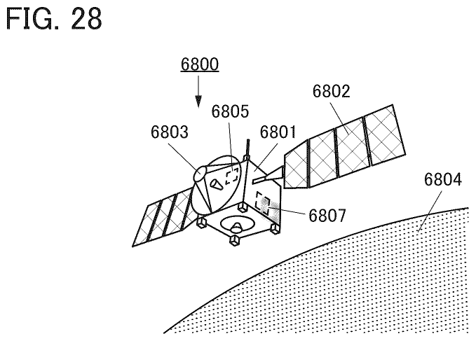

In this embodiment, specific examples of the case where the semiconductor device of one embodiment of the present invention is used in a device for space will be described with reference to FIG. 28.

The semiconductor device of one embodiment of the present invention includes an OS transistor. A change in electrical characteristics of the OS transistor due to radiation irradiation is small. That is, the OS transistor is highly resistant to radiation, and thus can be suitably used even in an environment where radiation can enter. For example, the OS transistor can be suitably used in outer space.

FIG. 28 illustrates an artificial satellite 6800 as an example of a device for space. The artificial satellite 6800 includes a body 6801, a solar panel 6802, an antenna 6803, a secondary battery 6805, and a control device 6807. Note that in FIG. 28, a planet 6804 in outer space is illustrated as an example. Note that outer space refers to, for example, space at an altitude greater than or equal to 100 km, and outer space described in this specification may include one or more of thermosphere, mesosphere, and stratosphere.

The amount of radiation in outer space is 100 or more times that on the ground. Note that examples of radiation include electromagnetic waves (electromagnetic radiation) typified by X-rays and gamma rays and particle radiation typified by alpha rays, beta rays, neutron beams, proton beams, heavy-ion beams, meson beams, and the like.

When the solar panel 6802 is irradiated with sunlight, electric power required for the operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for the operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device including the OS transistor of one embodiment of the present invention is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can be configured to include a sensor. For example, when configured to include a visible light sensor, the artificial satellite 6800 can have a function of sensing sunlight reflected by a ground-based object. Alternatively, when configured to include a thermal infrared sensor, the artificial satellite 6800 can have a function of sensing thermal infrared rays emitted from the surface of the earth. Thus, the artificial satellite 6800 can have a function of an earth observing satellite, for example.

Although the artificial satellite is described as an example of a device for space in this embodiment, one embodiment of the present invention is not limited thereto. The semiconductor device of one embodiment of the present invention can be suitably used for a device for space such as a spacecraft, a space capsule, or a space probe, for example.

### REFERENCE NUMERALS

10: memory cell, 11: memory layer, 15: memory cell array, 22: PSW, 23: PSW, 31: peripheral circuit, 32: control circuit, 33: voltage generation circuit, 41: peripheral circuit, 42: row decoder, 43: row driver, 44: column decoder, 45: column driver, 46: sense amplifier, 47: input circuit, 48: output circuit, 50: driver circuit layer, 110: memory device, 111t: memory cell, 111: memory cell, 112a: transistor, 112b: transistor, 112: transistor, 113t: capacitor, 113: capacitor, capacitor element, 114: transistor, 115: transistor, 120: memory cell array, 121: electrode, 122t: electrode, 122: electrode, 123t: insulating layer, 123: insulating layer, 130: substrate, 131: semiconductor layer, 132: gate insulating layer, 133: gate electrode, 134a: electrode, 134b: electrode, 135: conductive layer, 136: conductive layer, 137: conductive layer, 138: wiring, 139: wiring, 150: memory device, 151: capacitor, 160: conductor, 181: insulator, 183: insulator, 185: insulator, 201a: transistor, 201b: transistor, 201: transistor, 202a: transistor, 202b: transistor, 202: transistor, 203a: transistor, 203b: transistor, 203: transistor, 205a: conductor, 205b: conductor, 205t: conductor, 205: conductor, 209a: conductor, 209b: conductor, 209: conductor, 210: insulator, 212: insulator, 214: insulator, 215: insulator, 216a: insulator, 216b: insulator, 222: insulator, 224: insulator, 230a: metal oxide, 230b: metal oxide, 230: metal oxide, 231: conductor, 232: conductor, 240a: conductor, 240b: conductor, 240: conductor, 242a: conductor, 242b: conductor, 242c: conductor, 242d: conductor, 242e: conductor, 242: conductor, 253: insulator, 254: insulator, 258: opening, 260: conductor, 275: insulator, 280: insulator, 282: insulator, 285: insulator, 287: insulator, 291a: opening, 291b: opening, 292a: opening, 292b: opening, 293a: opening, 293b: opening. 294a: opening, 294b: opening, 300: transistor, 311: substrate, 313: semiconductor region, 314a: low-resistance region, 314b: low-resistance region, 315: insulator, 316: conductor, 320: insulator, 322: insulator, 324: insulator, 326: insulator, 328: conductor, 330: conductor, 600: circuit, 652: AND circuit, 653: analog switch, 654: analog switch, 661: transistor, 662: transistor, 663: transistor, 664: transistor, 666: transistor, 700: electronic component, 702: printed circuit board, 704: circuit board, 711: mold, 712: land, 713: electrode pad, 714: wire, 730: electronic component, 731: interposer, 732: package substrate, 733: electrode, 735: semiconductor device, 1200: chip, 1201: package substrate, 1202: bump, 1203: motherboard, 1204: GPU module, 1211: CPU, 1212: GPU, 1213: analog arithmetic unit, 1214: memory controller, 1215: interface, 1216: network circuit, 1221: DRAM, 1222: flash memory, 5110: SD card, 5111: housing, 5112: connector, 5113: substrate, 5115: controller chip, 5150: SSD, 5151: housing, 5152: connector, 5153: substrate, 5155: memory chip, 5156: controller chip, 5200: portable game machine, 5201: housing, 5202: display portion, 5203: button, 5300: desktop information terminal, 5301: main body, 5302: display portion, 5303: keyboard, 5400: ICD main unit, 5401: battery, 5402: wire, 5403: wire, 5404: antenna, 5405: subclavian vein, 5406: superior vena cava, 5500: information terminal, 5510: housing, 5511: display portion, 5600: computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 5700: automobile, 5800: electric refrigerator-freezer, 5801: housing, 5802: refrigerator door, 5803: freezer door, 5900: information terminal, 5901: housing, 5902: display portion, 5903: operation switch, 5904: operation switch, 5905: band, 6100: expansion device, 6101: housing, 6102: cap, 6103: USB connector, 6104: substrate, 6106: controller chip, 6240: digital camera, 6241: housing, 6242: display portion, 6243: operation switch, 6244: shutter button, 6246: lens, 6300: video camera, 6301: first housing, 6302: second housing, 6303: display portion, 6304: operation switch, 6305: lens, 6306: joint, 6800: artificial satellite, 6801: body, 6802: solar panel, 6803: antenna, 6804: planet, 6805: secondary battery, 6807: control device, 7500: stationary game machine, 7520: main body, 7522: controller

1. A memory device comprising:
a first transistor;
a second transistor;
a third transistor;
a first capacitor; and
a second capacitor,
wherein the first capacitor comprises a first electrode and a second electrode,
wherein the second capacitor comprises the first electrode and a third electrode,
wherein one of a source and a drain of the first transistor is electrically connected to the second electrode,
wherein one of a source and a drain of the second transistor is electrically connected to the third electrode,
wherein a gate of the third transistor is electrically connected to the second electrode,
wherein the first electrode comprises a portion overlapping with the second electrode, the third electrode, the first transistor, and the second transistor, and
wherein the first electrode is supplied with a fixed potential or a ground potential.

2. The memory device according to claim 1,
wherein the first electrode comprises a portion positioned above the first transistor and a portion positioned on a side of the first transistor.

3. The memory device according to claim 1, further comprising a connection electrode,
wherein the other of the source and the drain of the first transistor is electrically connected to the connection electrode, and
wherein the other of the source and the drain of the second transistor is electrically connected to the connection electrode.

4. The memory device according to claim 3,
wherein a first conductive layer is configured to function as the other of the source and the drain of the first transistor,
wherein a second conductive layer is configured to function as the other of the source and the drain of the second transistor, and
wherein the connection electrode comprises a portion in contact with a top surface of the first conductive layer, a portion in contact with a side surface of the first conductive layer, a portion in contact with a top surface of the second conductive layer, and a portion in contact with a side surface of the second conductive layer.

5. The memory device according to claim 3, further comprising a fourth transistor and a third capacitor,
wherein the fourth transistor and the third capacitor are positioned below the first transistor,
wherein the third capacitor comprises a fourth electrode and a fifth electrode,
wherein the fourth electrode is supplied with a fixed potential or a ground potential,
wherein one of a source and a drain of the fourth transistor is electrically connected to the fifth electrode, and
wherein the other of the source and the drain of the fourth transistor is electrically connected to the connection electrode.

6. The memory device according to claim 5,
wherein a third conductive layer is configured to function as the other of the source and the drain of the fourth transistor, and
wherein the connection electrode comprises a portion in contact with a top surface of the third conductive layer and a portion in contact with a side surface of the third conductive layer.

7. The memory device according to claim 5,
wherein the first electrode comprises a portion positioned on a side of the fourth transistor.

8. The memory device according to claim 7,
wherein the fourth electrode is electrically connected to the first electrode.

9. The memory device according to claim 5,
wherein the first transistor comprises a semiconductor layer and a gate electrode,
wherein the fourth electrode comprises a portion positioned below the first transistor, and
wherein the gate electrode comprises a portion overlapping with the fourth electrode with the semiconductor layer therebetween.

10. The memory device according to claim 1,
wherein each of the first electrode and the second electrode has a flat-plate shape.

11. The memory device according to claim 1,
wherein a top surface of the second electrode has a depressed portion, and
wherein the first electrode comprises a protruding portion engaging with the top surface of the second electrode.

12. A memory device comprising:
a first transistor;
a second transistor;
a first capacitor; and
a second capacitor,
wherein the first capacitor comprises a first electrode and a second electrode,
wherein the second capacitor comprises the first electrode and a third electrode,
wherein one of a source and a drain of the first transistor is electrically connected to the second electrode,
wherein one of a source and a drain of the second transistor is electrically connected to the third electrode,
wherein a first conductive layer comprising a region configured to function as the first electrode comprises a portion over and overlapping with the second electrode, the third electrode, the first transistor, and the second transistor, and
wherein the first conductive layer comprises a portion provided below the second electrode and the third electrode.
